(19) United States
(12) Patent Application Publication
(10) Pub. No.: US 2018/0320066 A1
(43) Pub. Date: Nov. 8, 2018

(54) FORMULATION FOR PRINTED ELECTRONICS AND USE OF THE SAME IN ELECTRONIC DEVICE

(71) Applicant: GUANGZHOU CHINARAY OPTOELECTRONIC MATERIALS LTD., Guangzhou (CN)

(72) Inventors: Junyou PAN, Guangzhou (CN); Xi YANG, Guangzhou (CN); Ruifeng HE, Guangzhou (CN)

(21) Appl. No.: 15/775,396

(22) PCT Filed: Sep. 23, 2016
(86) PCT No.: PCT/CN2016/099783

§ 371 Date: May 11, 2018

(30) Foreign Application Priority Data
Nov. 12, 2015 (CN) 201510771747.1

(51) Int. Cl. C09K 11/02; C09K 11/56; C09K 11/88; C09K 11/54; C09D 11/52; C09D 11/033; C09D 11/037; H01L 51/00; C09K 11/06

(52) U.S. Cl. CPC C09K 11/025; H01L 51/5056; C09K 11/883; C09K 11/54; C09D 11/52; C09D 11/033; C09D 11/037; H01L 51/0072; H01L 51/0067; H01L 51/0085; C09K 11/06; H01L 51/0058; H01L 51/0056; H01L 51/0059; C09K 2211/185; C09K 2211/1029; C09K 2211/1011; C09K 11/565

(57) ABSTRACT

A formulation for printed electronics, comprising at least one functional material and at least one heteroaromatic-based organic solvent. The printing process of the formulation and use thereof in an electronic device, particularly in an electroluminescent device. An electronic device produced by utilizing the formulation.

### CROSS-REFERENCE TO RELATED APPLICATIONS

The present application is the national phase of International Application No. PCT/CN2016/100164, filed on Sep. 26, 2016, which claims priority to Chinese Application No. 201510769470.9, filed on Nov. 12, 2015, both of which are incorporated herein by reference in their entireties.

### TECHNICAL FIELD

The present disclosure relates to a formulation for printed electronics and a use thereof in a printed electronic device, particularly in an electroluminescent device.

### BACKGROUND

At present, an organic light-emitting diode (OLED) as a new generation display is typically manufactured by an evaporation method, resulting in a low material utilization, and the method requires a fine metal mask (FMM) that would increase the cost and decrease the yield. In order to solve the above problems, a printing technology for realizing a high-resolution full-color display attracts more and more attention. For example, a large-area functional material film can be manufactured by ink-jet printing at low cost. Compared with conventional semiconductor manufacture processes, the ink-jet printing has great advantages and potential due to low energy consumption, low water consumption and environmentally friendly property thereof. Another new display technology is quantum dot light emitting diode (QLED), which cannot be manufactured by an evaporation method but only can be manufactured through printing. Therefore, in order to realize a printed display, it is necessary to make a breakthrough in printing inks and solve principal problems of corresponding printing processes. Viscosity and surface tension are important parameters affecting the printing inks and the printing processes. A promising printing ink requires suitable viscosity and surface tension.

Organic semiconductor materials have gained widespread attention and made remarkable progress in electronic and optoelectronic devices due to solution processability thereof. The solution processability allows an organic functional material to form a thin film of such functional material in a device through certain coating and printing processes. Such technology can effectively reduce the processing cost of electronic and optoelectronic devices and satisfy the need of large-area manufacturing. Up to now, a plurality of companies have reported organic semiconductor material printing inks, for example: KATEEVA, INC disclosed an ink comprising a small molecular organic material based on an ester solvent applicable for printing an OLED (US2015044802A1); UNIVERSAL DISPLAY CORPORATION disclosed a printable ink comprising a small molecular organic material based on an aromatic ketone or aromatic ether solvent (US20120205637); SEIKO EPSON CORPORATION disclosed a printable ink comprising an organic polymer material based on a substituted benzene derivative solvent. Other examples relating to organic functional material printing inks include: CN102408776A, CN103173060A, CN103824959A, CN1180049C, CN102124588B, US2009130296A1 and US2014097406A1, etc.

Another type of functional materials suitable for printing is inorganic nanomaterial, particularly quantum dots. Quantum dots are a nano-sized semiconductor material having the quantum confinement effect. Quantum dots can emit fluorescent light of specific energy when stimulated by light or electricity, and color (energy) of such fluorescent light is determined by the chemical compositions, particle size and shape of the quantum dots. Therefore, regulation of the particle size and shape of the quantum dots can effectively control the electronic and optical properties of the quantum dots. At present, many countries are conducting research in applications of quantum dots for full-color emission, mainly in the display field. Recently, electroluminescent devices including quantum dots as a light emitting layer (QLED) have been developed rapidly and lifetime of such devices is prolonged greatly, as reported by Peng et al., Nature Vol51596 (2015) and Qian et al., Nature Photonics Vol9259 (2015). Up to now, a plurality of companies have reported quantum dot inks for printing: Nanoco Technologies Ltd. in the United Kingdom disclosed a method of a printable ink formulation containing nanoparticles (CN101878535B). A printable nanoparticle ink and a corresponding film containing nanoparticles are obtained by selecting a suitable solvent such as toluene and dodecylselenol. Samsung Electronics disclosed a quantum dot ink for ink-jet printing (U.S. Pat. No. 8,765,014B2). The ink contains a certain amount of quantum dots, an organic solvent and a polyalcohol additive. A quantum dot film is printed from the ink to manufacture a quantum dot electroluminescent device. QD Vision Inc. disclosed a quantum dot ink formulation, comprising a host material, a quantum dot material and an additive (US2010264371A1).

Other patent literature relating to quantum dot printing inks includes US2008277626A1, US2015079720A1, US2015075397A1, TW201340370A, US2007225402A1, US2008169753A1, US2010265307A1, US2015101665A1 and WO2008105792A2.

However, in these disclosed patent documents, all quantum dot inks include other additives such as alcohol polymer for regulating physical parameters of the inks. Introduction of insulating polymer additives tends to reduce charge transporting ability of films, negatively affects optoelectronic properties of devices, and thus limits applications of quantum dot inks in optoelectronic devices.

### SUMMARY

An object of the present disclosure is to provide a formulation for printed electronics.

Specific technical schemes of the present disclosure are described as follows.

A formulation for printed electronics comprises at least one functional material and a solvent system including at least one organic solvent, wherein the organic solvent includes at least one heteroaromatic-based organic solvent having formula (I):

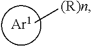

wherein Ar¹ is a heteroaromatic ring containing 5 to 10 carbon atoms, n is an integer equal to or larger than 0, and R is a substituent group. The heteroaromatic-based organic solvent having formula (I) has a boiling point equal to or larger than 150° C. and can be evaporated from the solvent system to allow a film containing inorganic nanomaterial to be formed.

In one embodiment of the formulation for printed electronics, the heteroaromatic-based organic solvent having formula (I) has a viscosity at 25° C. from 1 cPs to 100 cPs.

In one embodiment of the formulation for printed electronics, the heteroaromatic-based organic solvent having formula (I) has a surface tension at 25° C. from 19 dyne/cm to 50 dyne/cm.

In one embodiment of the formulation for printed electronics, the heteroaromatic-based organic solvent having formula (I) has a structure selected from one of formulas as follows:

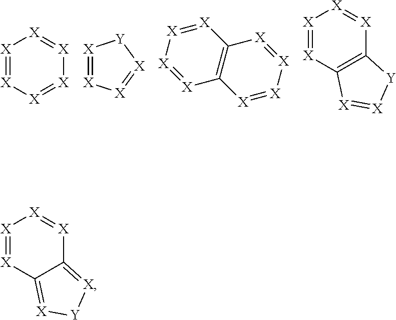

wherein,

X is CR¹ or N,

and Y is selected from CR²R³, SiR⁴R⁵, NR⁶, C(═O), S, S(═O)₂ or O;

in each formula, at least one X or Y is a non-carbon atom (i.e., a heteroatom);

and R¹, R², R³, R⁴, R⁵ and R⁶ each are independently selected from H, D, straight chain alkyl, straight chain alkoxy or straight chain thioalkoxy each containing 1 to 20 carbon atoms, branched or cyclic alkyl, branched or cyclic alkoxy, branched or cyclic thioalkoxy or branched or cyclic silyl each containing 3 to 20 carbon atoms, C₁-C₂₀ substituted keto, C₂-C₂₀ alkoxycarbonyl, C₇-C₂₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 40-membered aromatic or heteroaromatic rings, or 5- to 40-membered aryloxy or heteroaryloxy. When one or more of R¹, R², R³, R⁴, R⁵ and R⁶ exist simultaneously, they can exist independently or can form a monocyclic or a polycyclic aliphatic or aromatic ring system with each other and/or with a ring linked to the functional groups.

In one embodiment of the formulation for printed electronics, Ar¹ of formula (I) is selected from structural units as follows:

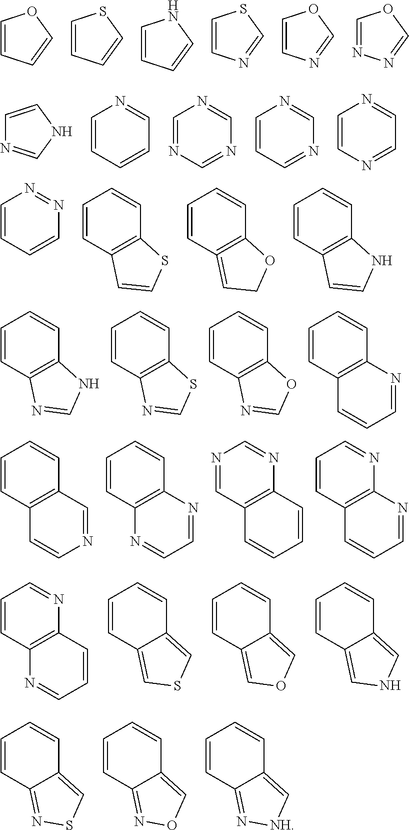

In one embodiment of the formulation for printed electronics, R of formula (I) is selected from straight chain alkyl, straight chain alkoxy or straight chain thioalkoxy each containing 1 to 20 carbon atoms, branched or cyclic alkyl, branched or cyclic alkoxy, branched or cyclic thioalkoxy or branched or cyclic silyl each containing 3 to 20 carbon atoms, C₁-C₂₀ substituted keto, C₂-C₂₀ alkoxycarbonyl, C₇-C₂₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 40-membered aromatic or heteroaromatic rings, or 5- to 40-membered aryloxy or heteroaryloxy, wherein one or more of R can exist independently or can form a monocyclic or a polycyclic aliphatic or aromatic ring system with each other and/or with a ring linked to the functional groups.

In one embodiment of the formulation for printed electronics, the heteroaromatic-based organic solvent having formula (I) is selected from 2-phenylpyridine, 3-phenylpyridine, 4-(3-phenylpropyl)pyridine, quinoline, isoquinoline, 8-hydroxyquinoline, methyl 2-furoate, ethyl 2-furoate or any mixture thereof.

In one embodiment of the formulation for printed electronics, the solvent system can be a mixed solvent further including at least one other solvent, wherein the organic solvent having formula (I) accounts for 50% or above of the total weight of the mixed solvent.

In one embodiment of the formulation for printed electronics, the functional material is an inorganic nanomaterial.

In one embodiment of the formulation for printed electronics, the functional material is a quantum dot material, which has a monodisperse particle size distribution, and shape of which can be selected from spherical nano-morphology, cubic nano-morphology, rodlike nano-morphology, or branched structure nano-morphology.

In one embodiment of the formulation for printed electronics, the functional material is a luminescent quantum dot material capable of emitting light having a wavelength between 380 nm and 2500 nm.

In one embodiment of the formulation for printed electronics, the formulation for printed electronics comprises an inorganic functional material, which is selected from binary or multinary semiconductor compounds of Group IV, II-VI, II-V, III-V, III-VI, IV-VI, I-III-VI, II-IV-VI and II-IV-V of the Periodic Table of the Elements, or any mixture thereof.

In one embodiment of the formulation for printed electronics, the functional material is a perovskite nanoparticle material, such as a luminescent perovskite nanomaterial, a metal nanoparticle material, a metal oxide nanoparticle material, or any mixture thereof.

In one embodiment of the formulation for printed electronics, the functional material is an organic functional material.

In one embodiment of the formulation for printed electronics, the organic functional material can be selected from a hole injection material (HIM), a hole transport material (HTM), an electron transport material (ETM), an electron injection material (EIM), an electron blocking material (EBM), a hole blocking material (HBM), an emitter, a host material, an organic dye, and any mixture thereof.

In one embodiment of the formulation for printed electronics, the organic functional material includes at least one host material and at least one emitter.

In one embodiment of the formulation for printed electronics, the formulation for printed electronics comprises 0.3%-30% by weight of the functional material, and 70%-99.7% by weight of the solvent system.

The present disclosure further provides an electronic device, which comprises a functional layer printed or coated from the formulation for printed electronics described above, wherein the heteroaromatic-based organic solvent having formula (I) can be evaporated from the solvent system to form a functional film.

In one embodiment of the present disclosure, the electronic device can be selected from a quantum dot light emitting diode (QLED), a quantum dot photovoltaic cell (QPV), a quantum dot light emitting electrochemical cell (QLEEC), a quantum dot field effect transistor (QFET), a quantum dot light emitting field effect transistor, a quantum dot laser, a quantum dot sensor, an organic light emitting diode (OLED), an organic photovoltaic cell (OPV), an organic light emitting electrochemical cell (OLEEC), an organic field effect transistor (OFET), an organic light emitting field effect transistor, an organic laser, an organic sensor, etc.

The present disclosure further provides a method for preparing a functional material film, wherein any one of the formulations for printed electronics described above is coated on a substrate through a printing or coating process, which can be selected from but not limited to ink-jet printing, nozzle printing, typographic printing, screen printing, dip coating, spin coating, blade coating, roller printing, torsion roller printing, lithographic printing, flexographic printing, rotary printing, spray coating, brush coating, pad printing, slot die coating, etc.

The present disclosure further provides a printing process of the formulation for printed electronics described above, and a use of the formulation for printed electronics in an electronic device, particularly in an electroluminescent device.

Beneficial effects of the present disclosure include that viscosity and surface tension of the formulation for printed electronics can be adjusted to an appropriate scope in use according to a specific printing process, particularly the ink-jet printing, thus facilitating the printing process and forming a film with a uniform surface. Moreover, the organic solvent can be removed effectively by a post treatment process, such as a heat treatment process or a vacuum treatment process, and thus ensuring performance of the electronic device. Accordingly, the present disclosure provides the printing ink, particularly the printing ink comprising the quantum dots and the organic semiconductor material, for preparing a high-quality functional film to provide an effective technical solution for printed electronics or optoelectronic devices.

### BRIEF DESCRIPTION OF THE DRAWINGS

FIG. 1 is a structural view of a light emitting device according to one embodiment of the present disclosure, wherein 101 is a substrate, 102 is an anode, 103 is a hole injection layer (HIL) or a hole transport layer (HTL), 104 is a light-emitting layer (an electroluminescent device) or a light-absorbing layer (a photovoltaic cell), 105 is an electron injection layer (EIL) or an electron transport layer (ETL), and 106 is a cathode.

### DETAILED DESCRIPTION

The present disclosure relates to a formulation for printed electronics, a printing process of the formulation and a use of the formulation in an electronic device, particularly in an optoelectronic device, and more particularly in an electroluminescent device. The present disclosure further relates to an electronic device prepared from the formulation.

The present disclosure will be described in detail below in order to make purposes, technical schemes, and effects of the present disclosure more clear and definite. It should be understood that detailed descriptions and specific embodiments described herein are used to explain the present disclosure only, but not intended to limit the scope of the disclosure.

In the description of the present application, terms of “formulation for printed electronics” and “printing ink” or “ink” have the same meaning, and can be interchangeable.

In one embodiment, the present disclosure provides a formulation for printed electronics, which comprises at least one functional material and a solvent system including at least one organic solvent, wherein the organic solvent includes at least one heteroaromatic-based organic solvent having formula (I):

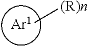

wherein Ar¹ is a heteroaromatic ring containing 5 to 10 carbon atoms, n is an integer equal to or larger than 0, and R is a substituent group. The heteroaromatic-based organic solvent having formula (I) has a boiling point equal to or higher than 120° C. and can be evaporated from the solvent system thereby forming a functional material film.

In the heteroaromatic-based organic solvent having formula (I), Ar¹ is a heteroaromatic ring containing 5 to 10 carbon atoms. A heteroaromatic group refers to a hydrocarbyl having at least one heteroaromatic ring (having a heteroatom), which can be a monocyclic group or a polycyclic ring system. The polycyclic ring system may have two or more rings, among which two adjacent rings share two carbon atoms to form a fused ring. And at least one ring of the polycyclic ring system is a heteroaromatic ring.

Specifically, examples of the heteroaromatic group can be selected from but not limited to furan, benzofuran, thiophene, benzothiophene, pyrrole, pyrazole, triazole, imidazole, oxazole, oxadiazole, thiazole, tetrazole, indole, carbazole, pyrroloimidazole, pyrrolopyrrole, thienopyrrole, thienothiophene, furopyrrole, furofuran, thienofuran, benzisoxazole, benzisothiazole, benzimidazole, pyridine, pyrazine, pyridazine, pyrimidine, triazine, quinoline, isoquinoline, phthalazine (cinnoline), quinoxaline, phenanthridine, perimidine, quinazoline, quinazolinone, and derivatives thereof.

In some embodiments, a total number of atoms other than H of every substituent group R in formula (I) is equal to or larger than 2. The atoms other than H described herein include, but are not limited to C, Si, N, P, O, S, F, Cl, Br, I, etc. For example, a methoxy substituent group and two chlorine substituent groups thereof are all included in the scope of the present disclosure. In some embodiments, a total number of atoms other than H of every substituent group R is equal to or larger than 2, in one embodiment is 2-20, in another embodiment is 2-10, and in yet another embodiment is 3-10.

In some embodiments of the present disclosure, the heteroaromatic-based organic solvent having formula (I), included in the formulation for printed electronics, may have a structure selected from one of formulas as follows:

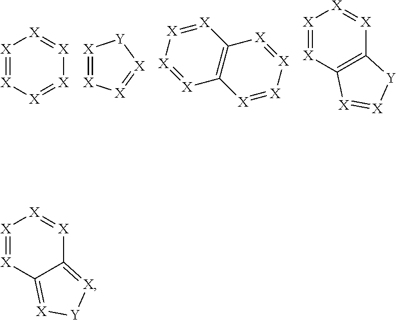

where,

X is CR¹ or N,

and Y is selected from CR²R³, SiR⁴R⁵, NR⁶, C(═O), S, S(═O)₂ or O;

in each formula, at least one X or Y is a non-carbon atom (i.e., the heteroatom);

and R¹, R², R³, R⁴, R⁵ and R⁶ each can be independently selected from but not limited to H, D, straight chain alkyl, straight chain alkoxy or straight chain thioalkoxy each containing 1 to 20 carbon atoms, branched or cyclic alkyl, branched or cyclic alkoxy, branched or cyclic thioalkoxy or branched or cyclic silyl each containing 3 to 20 carbon atoms, C₁-C₂₀ substituted keto, C₂-C₂₀ alkoxycarbonyl, C₇-C₂₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 40-membered aromatic or heteroaromatic rings, or 5- to 40-membered aryloxy or heteroaryloxy. When one or more of R¹, R², R³, R⁴, R⁵ and R⁶ exist simultaneously, they can exist independently or can form a monocyclic or a polycyclic aliphatic or aromatic ring system with each other and/or with a ring linked to the functional groups.

In some preferred embodiments, R¹, R², R³, R⁴, R⁵ and R⁶ each can be independently selected from H, D, straight chain alkyl, straight chain alkoxy or straight chain thioalkoxy each containing 1 to 10 carbon atoms, branched or cyclic alkyl, branched or cyclic alkoxy, branched or cyclic thioalkoxy or branched or cyclic silyl each containing 3 to 10 carbon atoms, C₁-C₁₀ substituted keto, C₂-C₁₀ alkoxycarbonyl, C₇-C₁₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 20-membered aromatic or heteroaromatic rings, or 5- to 20-membered aryloxy or heteroaryloxy. When one or more of R¹, R², R³, R⁴, R⁵ and R⁶ exist simultaneously, they can exist independently or can form a monocyclic or a polycyclic aliphatic or aromatic ring system with each other and/or with a ring linked to the functional groups.

In some embodiments of the present disclosure, the heteroaromatic-based organic solvent having formula (I) included in the formulation for printed electronics has formula (I), wherein Ar¹ can be selected from one of structural units as follows:

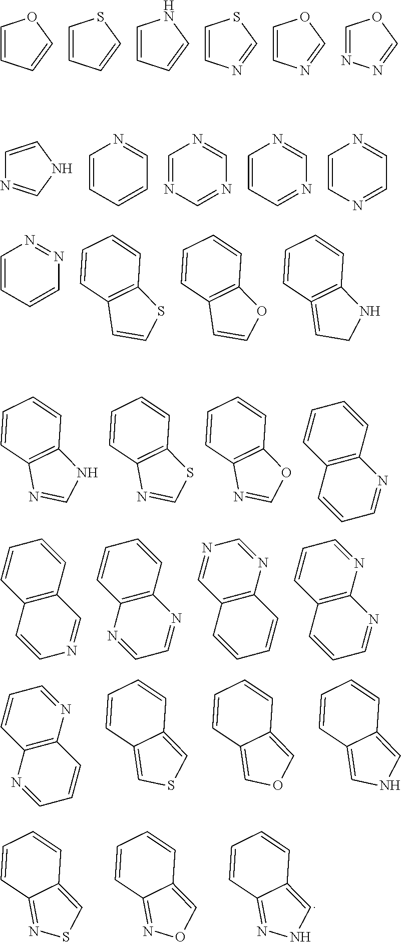

In some embodiments, R of formula (I) can be selected from but not limited to straight chain alkyl, straight chain alkoxy or straight chain thioalkoxy each containing 1 to 20 carbon atoms, branched or cyclic alkyl, branched or cyclic alkoxy, branched or cyclic thioalkoxy or branched or cyclic silyl each containing 3 to 20 carbon atoms, C₁-C₂₀ substituted keto, C₂-C₂₀ alkoxycarbonyl, C₇-C₂₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 40-membered aromatic or heteroaromatic rings, or 5- to 40-membered aryloxy or heteroaryloxy, wherein one or more of R can exist independently or can form a monocyclic or a polycyclic aliphatic or aromatic ring system with each other and/or with a ring linked to the functional groups.

In some embodiments, at least one substituent group R of formula (I) can be selected from but not limited to straight chain alkyl, straight chain alkoxy or straight chain thioalkoxy each containing 1 to 10 carbon atoms, branched or cyclic alkyl, branched or cyclic alkoxy, branched or cyclic thioalkoxy or branched or cyclic silyl each containing 3 to 10 carbon atoms, C₁-C₁₀ substituted keto, C₂-C₁₀ alkoxycarbonyl, C₇-C₁₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 20-membered aromatic or heteroaromatic rings, or 5- to 20-membered aryloxy or heteroaryloxy, wherein one or more of R can exist independently or can form a monocyclic or a polycyclic aliphatic or aromatic ring system with each other and/or with a ring linked to the functional groups.

The heteroaromatic-based organic solvent having formula (I) for dissolving the functional material should be selected in consideration of its boiling point parameter. In some embodiments of the present disclosure, the heteroaromatic-based organic solvent having formula (I) has a boiling point equal to or larger than 150° C. In some embodiments, the heteroaromatic-based organic solvent having formula (I) has a boiling point equal to or larger than 180° C. In some embodiments, the heteroaromatic-based organic solvent having formula (I) has a boiling point equal to or larger than 200° C. In some embodiments, the heteroaromatic-based organic solvent having formula (I) has a boiling point equal to or larger than 250° C. In other embodiments, the heteroaromatic-based organic solvent having formula (I) has a boiling point equal to or larger than 275° C., or equal to or larger than 300° C. When the boiling point is within the above ranges, it is benefit for protecting a nozzle of ink-jet printing head from blocking. The heteroaromatic-based organic solvent having formula (I) can be evaporated from the solvent system thereby forming a functional material film.

In some embodiments of the present disclosure, the heteroaromatic-based organic solvent having formula (I) included in the formulation for printed electronics has a surface tension at 25° C. from 19 dyne/cm to 50 dyne/cm.

The heteroaromatic-based organic solvent having formula (I) for dissolving the functional material should be selected in consideration of its surface tension parameter. A suitable surface tension parameter of an ink is suitable for a specific substrate and a specific printing process. For example, referring to ink-jet printing, in one embodiment, the heteroaromatic-based organic solvent having formula (I) has a surface tension at 25° C. from 19 dyne/cm to 50 dyne/cm. In another embodiment, the heteroaromatic-based organic solvent having formula (I) has a surface tension at 25° C. from 22 dyne/cm to 35 dyne/cm. In yet another embodiment, the heteroaromatic-based organic solvent having formula (I) has a surface tension at 25° C. from 25 dyne/cm to 33 dyne/cm.

In one embodiment, the ink of the present disclosure has a surface tension at 25° C. from 19 dyne/cm to 50 dyne/cm, in another embodiment, the ink of the present disclosure has a surface tension at 25° C. from 22 dyne/cm to 35 dyne/cm, and in yet another embodiment, the ink of the present disclosure has a surface tension at 25° C. from 25 dyne/cm to 33 dyne/cm.

A formulation according to the present disclosure comprises the heteroaromatic-based organic solvent having formula (I), which has a viscosity at 25° C. from 1 cPs to 100 cPs.

The heteroaromatic-based organic solvent having formula (I) for dissolving the functional material should be selected in consideration of its viscosity parameter. Viscosity can be adjusted by various methods, e.g., by selecting a suitable organic solvent and controlling a concentration/weight ratio of the functional material in ink. An amount of the solvent system including the heteroaromatic-based organic solvent having formula (I) in a printing ink can be adjusted conveniently within a proper range in accordance with a printing process employed. Typically, a weight ratio of the functional material included in the formulation for printed electronics is within a range of 0.3-30 wt %, in one embodiment, a weight ratio of the functional material included in the formulation for printed electronics is within a range of 0.5-20 wt %, in another embodiment, a weight ratio of the functional material included in the formulation for printed electronics is within a range of 0.5-15 wt %, and in yet another embodiment, a weight ratio of the functional material included in the formulation for printed electronics is within a range of 0.5-10 wt %. In one embodiment, the viscosity of the heteroaromatic-based organic solvent having formula (I) is less than 100 cps. In another embodiment, the viscosity of the heteroaromatic-based organic solvent having formula (I) is less than 50 cps. In yet another embodiment, the viscosity of the heteroaromatic-based organic solvent having formula (I) is between 1.5 and 20 cps. Herein, the viscosity refers to a viscosity at an ambient temperature during printing, typically at 15-30° C., in one embodiment, the viscosity refers to a viscosity at an ambient temperature during printing, typically at 18-28° C., in another embodiment, the viscosity refers to a viscosity at an ambient temperature during printing, typically at 20-25° C., and in yet another embodiment, the viscosity refers to a viscosity at an ambient temperature during printing, typically at 23-25° C. Such formulated formulation is especially suitable for ink-jet printing.

In one embodiment, the formulation for printed electronics formulated as above has a viscosity at 25° C. from 1 cps to 100 cps, in another embodiment from 1 cps to 50 cps, and in yet another embodiment from 1.5 cps to 20 cps.

A functional material film having a uniform thickness and a uniform formulation property can be formed from the ink containing the heteroaromatic-based solvent system having the boiling point, the surface tension parameter, and the viscosity parameter as described above.

Examples of the heteroaromatic-based organic solvent having formula (I) include, but is not limited to, 2-phenylpyridine, 3-phenylpyridine, 4-(3-phenylpropyl)pyridine, quinoline, isoquinoline, methyl 2-furoate, ethyl 2-furoate, etc.

In some embodiments, the printing ink of the present disclosure comprises a single heteroaromatic-based organic solvent having formula (I), such as quinoline or isoquinoline.

In other embodiments, the printing ink of the present disclosure comprises a mixture of two or more heteroaromatic-based organic solvents having formula (I).

In some embodiments, the organic solvent of the printing ink of the present disclosure is a mixture of quinoline and isoquinoline.

In other embodiments, the printing ink of the present disclosure comprises one heteroaromatic-based organic solvent having formula (I) and at least one other solvent, wherein the heteroaromatic-based organic solvent having formula (I) accounts for 50% or above of the total weight of the solvent mixture. In some embodiments, the heteroaromatic-based organic solvent having formula (I) accounts for at least 70% of the total weight of the solvent mixture. In one embodiment, the heteroaromatic-based organic solvent having formula (I) accounts for at least 80% of the total weight of the solvent mixture. In another embodiment, the heteroaromatic-based organic solvent having formula (I) accounts for at least 90% of the total weight of the solvent mixture, or the solvent mixture is substantially or totally consisting of the heteroaromatic-based organic solvent having formula (I).

In one embodiment, at least one other organic solvent is selected from substituted or unsubstituted aromatic solvents.

In some embodiments, the organic solvent included in the printing ink of the present disclosure is a mixture of quinoline and dodecylbenzene.

In some embodiments, the organic solvent included in the printing ink of the present disclosure is a mixture of isoquinoline and dodecylbenzene.

In some embodiments, the organic solvent included in the printing ink of the present disclosure is a mixture of quinoline and 3-phenoxytoluene.

In some embodiments, the organic solvent included in the printing ink of the present disclosure is a mixture of isoquinoline and 3-phenoxytoluene.

In other embodiments, examples of at least one other organic solvent include, but is not limited to, methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, 2-butanone, 1,2-dichloroethane, 3-phenoxyl toluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decahydronaphthalene, indene, or any mixture thereof.

The heteroaromatic-based solvent system according to the present disclosure can dissolve the functional material effectively, in other words, it can be used as a new solvent instead of a conventional solvent, such as toluene, xylene, chloroform, chlorobenzene, dichlorobenzene and n-heptane, for dissolving the functional material.

The printing ink may further comprise one or more components, such as surfactants, lubricants, wetting agents, dispersants, hydrophobing agents, and binders, for adjusting viscosity, film forming property, and improving adhesiveness, etc.

A functional film can be formed from the printing ink by various printing or coating technologies, wherein suitable printing or coating technologies include, but is not limited to, ink-jet printing, nozzle printing, typographic printing, screen printing, dip coating, spin coating, blade coating, roller printing, torsion roller printing, lithographic printing, flexographic printing, rotary printing, spray coating, brush coating, pad printing, slot die coating, etc. Embodiments of printing technologies include ink-jet printing, nozzle printing, and gravure printing. For detailed information of printing technologies and their requirements (such as solvent, concentration and viscosity) for the ink, please refer to Handbook of Print Media: Technologies and Production Methods, ISBN 3-540-67326-1 edited by Helmut Kipphan. Generally, different printing technologies require different properties of inks. For instance, ink-jet printing requires a printing ink having controlled surface tension, viscosity and wettability so that the printing ink can be sprayed smoothly through nozzles at a printing temperature (e.g., room temperature 25° C.) without getting dried in the nozzles or clogging the nozzles, or can form a continuous, smooth and defect-free film on a specific substrate.

The formulation for printed electronics according to the present disclosure comprises at least one functional material.

In the present disclosure, the functional material can be a material with certain optoelectronic functions, including but not limited to hole injection function, hole transport function, electron transport function, electron injection function, electron blocking function, hole blocking function, light emitting function, host function, and light absorbing function. The corresponding functional materials are respectively referred to as a hole injection material (HIM), a hole transport material (HTM), an electron transport material (ETM), an electron injection material (EIM), an electron blocking material (EBM), a hole blocking material (HBM), an emitter, a host material, and an organic dye.

The functional material can be an organic material or an inorganic material.

In one embodiment, at least one functional material included in the formulation for printed electronics is an inorganic nanomaterial.

In one embodiment, in the formulation for printed electronics, the inorganic nanomaterial is an inorganic semiconductor nanoparticle material.

In the present disclosure, a mean particle size of the inorganic nanomaterial is within a range from about 1 nm to about 1000 nm. In some embodiments, the mean particle size of the inorganic nanomaterial is between about 1 nm and about 100 nm. In some embodiments, the mean particle size of the inorganic nanomaterial is between about 1 nm and about 20 nm, and such as between 1 nm and 10 nm.

The inorganic nanomaterial can be formed in different shapes, including but not limited to a spherical shape, a cubic shape, a rodlike shape, a disc shape, a branched structure, or other different nanotopography, and a combination thereof.

In one embodiment, the inorganic nanomaterial is a quantum dot material, which has a very narrow and monodisperse particle size distribution, in other words, a size difference between particles is very small. In one embodiment, a root mean square deviation of the particle size of monodispersed quantum dots is less than 15% rms, in another embodiment, less than 10% rms, and in yet another embodiment, less than 5% rms.

In one embodiment, the inorganic nanomaterial is a luminescent material.

In one embodiment, the luminescent inorganic nanomaterial is a luminescent quantum dot material.

Typically, luminescent quantum dots can emit light of a wavelength between 380 nm and 2500 nm. For example, it is found that a wavelength of light emitted from quantum dots with CdS core is between 400 nm and 560 nm, a wavelength of light emitted from quantum dots with CdSe core is between 490 nm and 620 nm, a wavelength of light emitted from quantum dots with CdTe core is between 620 nm and 680 nm, a wavelength of light emitted from quantum dots with InGaP core is between 600 nm and 700 nm, a wavelength of light emitted from quantum dots with PbS core is between 800 nm and 2500 nm, a wavelength of light emitted from quantum dots with PbSe core is between 1200 nm and 2500 nm, a wavelength of light emitted from quantum dots with CuInGaS core is between 600 nm and 680 nm, a wavelength of light emitted from quantum dots with ZnCuInGaS core is between 500 nm and 620 nm, and a wavelength of light emitted from quantum dots with CuInGaSe core is between 700 nm and 1000 nm.

In one embodiment, the quantum dot material includes at least one of a material capable of emitting blue light having an emission peak wavelength between 450 nm and 460 nm, a material capable of emitting green light having an emission peak wavelength between 520 nm and 540 nm, a material capable of emitting red light having an emission peak wavelength between 615 nm and 630 nm, or any mixture thereof.

The quantum dots may have special chemical composition, morphology structure and/or particle size in order to emit light having a desired wavelength under an electrical stimulation.

A narrow particle size distribution of the quantum dots allows the quantum dots to have a narrower luminescent spectrum. In addition, particle size of quantum dots should be adjusted within the ranges described above according to the chemical composition and structure of the quantum dots in order to obtain the desired wavelengths.

In one embodiment, the luminescent quantum dots are semiconductor nanocrystals. Typically, a particle size of the semiconductor nanocrystals is within a range between about 2 nm and about 15 nm. In addition, the particle size of the quantum dots should be adjusted within the ranges described above according to the chemical composition and structure of the quantum dots in order to obtain the desired wavelengths.

The semiconductor nanocrystals include at least one semiconductor material, which can be selected from binary or multinary semiconductor compounds of Group IV, II-VI, II-V, III-V, III-VI, IV-VI, I-III-VI, II-IV-VI and II-IV-V of the Periodic Table of the Elements, or any mixture thereof. Specific examples of the semiconductor material include, but are not limited to, semiconductor compounds of Group IV elements, for example, including elementary substance such as Si and Ge and binary compounds such as SiC and SiGe; semiconductor compounds of Group II-VI elements, for example, including binary compounds such as CdSe, CdTe, CdO, CdS, CdSe, ZnS, ZnSe, ZnTe, ZnO, HgO, HgS, HgSe and HgTe, ternary compounds such as CdSeS, CdSeTe, CdSTe, CdZnS, CdZnSe, CdZnTe, CgHgS, CdHgSe, ZnSeS, ZnSeTe, ZnSTe, HgSeS, HgSeTe, HgSTe, HgZnS and HgSeSe, and quaternary compounds such as CgHgSeS, CdHgSeTe, CgHgSTe, CdZnSeS, CdZnSeTe, HgZnSeTe, HgZnSTe, CdZnSTe and HgZnSeS; semiconductor compounds of Group III-V elements, for example, including binary compounds such as AlN, AlP, AlAs, AlSb, GaN, GaP, GaAs, GaSb, InN, InP, InAs and InSb, ternary compounds such as AlNP, AlNAs, AlNSb, AlPAs, AlPSb, GaNP, GaNAs, GaNSb, GaPAs, GaPSb, InNP, InNAs, InNSb, InPAs, InPSb, and quaternary compounds such as GaAlNAs, GaAlNSb, GaAlPAs, GaInNP, GaInNAs, GaInNSb, GaInPAs, GaInPSb, InAlNP, InAlNAs, InAlNSb, InAlPAs and InAlPSb; and semiconductor compounds of Group IV-VI elements, for example, including binary compounds such as SnS, SnSe, SnTe, PbSe, PbS and PbTe, ternary compounds such as SnSeS, SnSeTe, SnSTe, SnPbS, SnPbSe, SnPbTe, PbSTe, PbSeS and PbSeTe, and quaternary compounds such as SnPbSSe, SnPbSeTe and SnPbSTe.

In one embodiment, the luminescent quantum dots include Group II-VI semiconductor materials, which can be selected from CdSe, CdS, CdTe, ZnO, ZnSe, ZnS, ZnTe, HgS, HgSe, HgTe, CdZnSe or any mixture thereof. In a suitable embodiment, CdSe and CdS can be applied in the luminescent quantum dots for visible light due to their synthesis processes developed well.

In another embodiment, the luminescent quantum dots include Group III-V semiconductor materials, which can be selected from InAs, InP, InN, GaN, InSb, InAsP, InGaAs, GaAs, GaP, GaSb, AlP, AlN, AlAs, AISb, CdSeTe, ZnCdSe, or any mixture thereof.

In another embodiment, the luminescent quantum dots include Group IV-VI semiconductor materials, which can be selected from PbSe, PbTe, PbS, PbSnTe, Tl₂SnTes, or any mixture thereof.

In one embodiment, a quantum dot has a core-shell structure, wherein the core and the shell identically or differently include one or more semiconductor materials.

The core of quantum dot can be selected from binary or multinary semiconductor compounds of Group IV, II-VI, II-V, III-V, III-VI, IV-VI, I-III-VI, II-IV-VI and II-IV-V elements of the Periodic Table of the Elements as described above. Specific examples for the core of quantum dot include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, Si, alloy thereof or any mixture thereof.

The shell of quantum dot includes a semiconductor material identical to or different than that of the core of quantum dot. A useful semiconductor material for the shell can be selected from binary or multinary semiconductor compounds of Group IV, II-VI, II-V, III-V, III-VI, IV-VI, I-III-VI, II-IV-VI and II-IV-V elements of the Periodic Table of the Elements as described above. Specific examples of the shell of quantum dot include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, Si, alloy thereof or any mixture thereof.

In the quantum dot having the core-shell structure, the shell can be formed of a single layer or a plurality of layers. The shell may include one or more semiconductor materials identical to or different from that of the core. In one embodiment, the shell has a thickness of about 1 to about 20 layers. In another embodiment, the shell has a thickness of about 5 to about 10 layers. In some embodiments, the core of quantum dot has a surface with two or more shells grown thereon.

In one embodiment, the semiconductor material used in the shell may have a bandgap larger than that of the semiconductor material used in the core. Especially in one embodiment, the core-shell has type I semiconductor heterojunction structure.

In another embodiment, the semiconductor material used in the shell may have a bandgap smaller than that of the semiconductor material used in the core.

In one embodiment, the semiconductor material used in the shell may have an atomic crystal structure identical or similar to that of the semiconductor material used in the core. Such selection contributes to reduced stress between the core and the shell to make the quantum dot more stable.

Suitable examples of the luminescent quantum dots having the core-shell structure include, but are not limited to, CdSe/CdS, CdSe/CdS/ZnS, CdSe/CdZnS and so on for emitting red light, CdZnSe/CdZnS, CdSe/ZnS and so on for emitting green light, and CdS/CdZnS, CdZnS/ZnS and so on for emitting blue light.

An embodiment of a method for preparing quantum dots is a colloidal growth method. In one embodiment, a method for preparing monodispersed quantum dots is selected from a hot-injection method and/or a heating-up method. These preparation methods are disclosed in the following document: NanoRes, 2009, 2, 425-447; Chem. Mater., 2015, 27 (7), pp 2246-2285.

In one embodiment, the surface of the quantum dot may have an organic ligand, which can control the growth process of the quantum dot, regulate the morphology of the quantum dot and reduce surface defects of the quantum dot, and thereby improving luminescent efficiency and stability of the quantum dot. The organic ligand can be selected from, but not limited to, pyridine, pyrimidine, furan, amine, alkyl phosphine, alkyl phosphine oxide, alkyl phosphonic acid or alkyl phosphinic acid, alkyl thiol, and the like. Specific examples of the organic ligand include, but are not limited to, tri-n-octylphosphine, tri-n-octylphosphine oxide, trihydroxypropylphosphine, tributylphosphine, tri(dodecyl)phosphine, dibutyl phosphite, tributyl phosphite, octadecyl phosphite, trilauryl phosphite, tridodecyl phosphite, triisodecyl phosphite, bis(2-ethylhexyl)phosphate, tri(tridecyl)phosphate, hexadecylamine, oleylamine, octadecylamine, dioctadecylamine, trioctadecylamine, bis(2-ethylhexyl)amine, octylamine, dioctylamine, trioctylamine, dodecylamine, didodecylamine, tridodecylamine, hexadecylamine, phenylphosphoric acid, hexylphosphonic acid, tetradecylphosphonic acid, octylphosphonic acid, n-octadecylphosphonic acid, propylene diphosphonic acid, dioctyl ether, diphenyl ether, octanethiol, dodecanethiol, and the like.

In another embodiment, the surface of the quantum dot may have an inorganic ligand. The quantum dot protected by the inorganic ligand can be obtained through ligand exchange with the organic ligand on the surface of quantum dot. Specific examples of the inorganic ligand include, but are not limited to, S²⁻, HS⁻, Se²⁻, HSe⁻, Te²⁻, HTe⁻, TeS₃²⁻, OH⁻, NH₂⁻, PO₄³⁻, MoO₄²⁻, etc.

In some embodiments, the surface of the quantum dot may have one or more same ligands or different ligands.

In one embodiment, a luminescent spectrum of the monodispersed quantum dots may have a symmetrical peak shape and a narrow full width at half maxima (FWHM). Typically, the better the monodispersity of the quantum dots, the more symmetrical the luminescence peak thereof, and the narrower the FWHM. In one embodiment, the FWHM of the luminescent spectrum of the quantum dots is smaller than 70 nm. In another embodiment, the FWHM of the luminescent spectrum of the quantum dots is smaller than 40 nm. In yet another embodiment, the FWHM of the luminescent spectrum of the quantum dots is smaller than 30 nm.

Typically, the luminescence quantum efficiency of the quantum dots is larger than 10%, in one embodiment, the luminescence quantum efficiency of the quantum dots is larger than 50%, in another embodiment, the luminescence quantum efficiency of the quantum dots is larger than 60%, and in yet another embodiment, the luminescence quantum efficiency of the quantum dots is larger than 70%.

In another embodiment, luminescent semiconductor nanocrystals are nanorods. Characteristics of the nanorods are different from those of spherical nanocrystal grains. For example, the nanorods emit light polarized axially in the length direction, but the spherical crystal grains emit light unpolarized. Nanorods have an excellent optical gain property, which allows them to be used as a laser gain material. In addition, luminescence of the nanorods can be turned on and off reversibly under the control of an external electric field. These properties of nanorods can be incorporated in a device of the present disclosure in certain circumstances.

In other embodiments, in the formulation for printed electronics of the present disclosure, the inorganic nanomaterial is perovskite nanoparticle material, particularly luminescent perovskite nanoparticle material.

The perovskite nanoparticle material may have a general structural formula of AMX₃, wherein A can be selected from organic amine or alkaline metal cations, M can be selected from metal cations, X can be selected from oxygen or halogen anions. Specific examples include, but are not limited to, CsPbCl₃, CsPb(Cl/Br)₃, CsPbBr₃, CsPb(I/Br)₃, CsPbI₃, CH₃NH₃PbCl₃, CH₃NH₃Pb(Cl/Br)₃, CH₃NH₃PbBr₃, CH₃NH₃Pb(I/Br)₃, CH₃NH₃PbI₃, etc.

In another embodiment, in the formulation for printed electronics of the present disclosure, the inorganic nanomaterial is a metal nanoparticle material, such as, a luminescent metal nanoparticle material.

Metal nanoparticles include, but are not limited to, nanoparticles of metal such as Cr, Mo, W, Ru, Rh, Ni, Ag, Cu, Zn, Pd, Au, Os, Re, Ir and Pt.

In another embodiment, the inorganic nanomaterial has a charge transport function.

In one embodiment, the inorganic nanomaterial has an electron transport ability. In one embodiment, such inorganic nanomaterial is selected from n-type semiconductor materials. Examples of n-type inorganic semiconductor materials include, but are not limited to, metal chalcogenide, metal pnictide, or elemental semiconductor, such as metal oxide, metal sulfide, metal selenide, metal telluride, metal nitride, metal phosphide, or metal arsenide. In one embodiment, n-type inorganic semiconductor materials can be selected from, but are not limited to, ZnO, ZnS, ZnSe, TiO₂, ZnTe, GaN, GaP, AlN, CdSe, CdS, CdTe, CdZnSe or any mixture thereof.

In some embodiments, the inorganic nanomaterial has a hole transport ability. In one embodiment, such inorganic nanomaterial can be selected from p-type semiconductor materials. The inorganic p-type semiconductor materials can be selected from NiOx, WOx, MoOx, RuOx, VOx, CuOx or any mixture thereof.

In some embodiments, the printing ink of the present disclosure may include at least two or more than two kinds of inorganic nanomaterials.

In another particularly embodiment, the formulation for printed electronics may include at least one kind of organic functional material.

The organic functional material can include, but is not limited to, a hole injection or transport material (HIM/HTM), a hole blocking material (HBM), an electron injection or transport material (EIM/ETM), an electron blocking material (EBM), an organic host material (Host), a singlet emitter (fluorescence emitter), a thermally activated delayed fluorescence material (TADF), a triplet emitter (phosphorescent emitter), particularly a luminescent organic metal complex, an organic dye.

Typically, solubility of the organic functional material in the heteroaromatic-based solvent of the present disclosure can be at least 0.2 wt %, in one embodiment is at least 0.3 wt %, in another embodiment is at least 0.6 wt %, in yet another embodiment is at least 1.0 wt %, and in yet another embodiment is at least 1.5 wt %.

The organic functional material can be a small molecular material or a polymer material. In the present disclosure, the small molecular organic material refers to a material of the molecular weight no more than 4000 g/mol, and a material of the molecular weight greater than 4000 g/mol is referred to as polymer.

In one embodiment, the functional material included in the formulation for printed electronics is the small molecular organic material.

In some embodiments, the organic functional material included in the formulation for printed electronics can include at least one host material and at least one emitter.

In one embodiment, the organic functional material can include one host material and one singlet emitter.

In another embodiment, the organic functional material can include one host material and one triplet emitter.

In another embodiment, the organic functional material can include one host material and one thermally activated delayed fluorescence material.

In other embodiments, the organic functional material can include the hole transport material (HTM), and in one embodiment, the HTM has a corsslinkable group.

Suitable small molecular organic functional materials of some embodiments are described below in more details, but the present disclosure is not limited to these materials.

1. HIM/HTM/EBM

A suitable organic HIM/HTM material can optionally include but is not limited to compounds having following structural units: phthalocyanine, porphyrin, amine, aromatic amine, biphenyl triarylamine, thiophene, thiophthene such as dithienothiophene and thiophthene, pyrrole, aniline, carbazole, indolocarbazole and derivatives thereof. In addition, a suitable HIM also includes, but is not limited to, polymer containing fluorocarbon, polymer containing conductive dopant, conductive polymer, such as PEDOT:PSS.

An electron blocking layer (EBL) is applied to block electrons from an adjacent functional layer, particularly, from a light emitting layer. In comparison with a light emitting device without a blocking layer, the presence of EBL will generally improve the light emitting efficiency. An electron blocking material (EBM) of the electron blocking layer (EBL) should have higher LUMO than an adjacent layer, such as the light emitting layer. In one embodiment, the EBM has a higher excited state level, such as a singlet state and a triplet state depending on the emitter, than the adjacent light emitting layer. Moreover, the EBM has a hole transport function. Generally, an HIM/HTM material with high LUMO level can be referred to as the EBM.

Examples of cyclic aromatic amine derivatives which can be used as HIM, HTM or EBM include but are not limited to the following general structures:

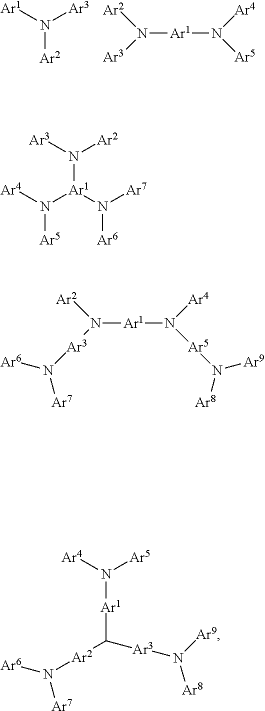

wherein Ar¹ to Ar⁹ each can be independently selected from cyclic aromatic hydrocarbon compounds such as benzene, biphenyl, triphenyl, benzo, naphthalene, anthracene, phenalene, phenanthrene, fluorene, pyrene, chrysene, perylene, azulene; heteroaromatic compounds such as dibenzothiophene, dibenzofuran, furan, thiophene, benzofuran, benzothiophene, carbazole, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzoimidazole, indazole, indolizine, benzoxazole, benzisoxazole, benzothiazole, quinoline, isoquinoline, phthalazine (cinnoline), quinazoline, quinoxaline, naphthalene, phthalein, pteridine, xanthene, acridine, phenazine, phenothiazine, phenoxazine, dibenzoselenophene, benzoselenophene, benzofuropyridine, indolocarbazole, pyridineindole, pyrrolodipyridine, furodipyridine, benzothienopyridine, thienopyridine, benzoselenophenopyridine and selenophenodipyridine; and a group having two to ten rings, which can be the same or different cyclic aromatic hydrocarbon groups or heteroaromatic groups linked directly or linked through, for example, at least one group as follows but not limited to: an oxygen atom, a nitrogen atom, a sulfur atom, a silicon atom, a phosphorous atom, a boron atom, a chain structural unit and a cyclic aliphatic group, wherein each Ar can be substituted further by a substituent group that can be selected from but not limited to hydrogen, alkyl, alkoxy, amino, alkenyl, alkynyl, aralkyl, heteroalkyl, aryl or heteroaryl.

In one aspect, Ar¹ to Ar⁹ can be independently selected from but not limited to the following functional groups:

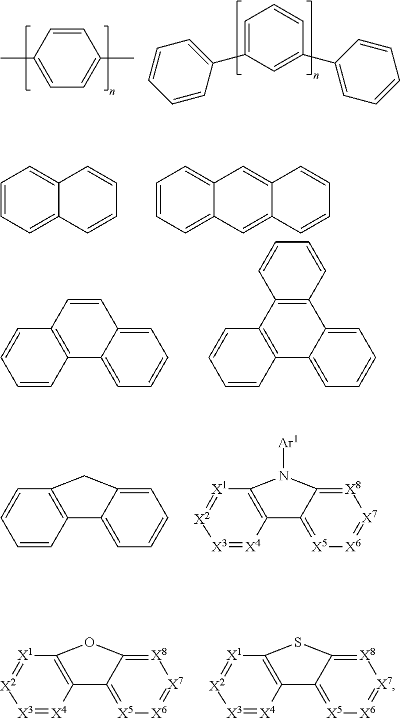

wherein n is an integer of 1 to 20; X¹ to X⁸ are CH or N; and Ar¹ is defined as above.

Examples of a metal complex as HTM or HIM include but not limited to the following general structure:

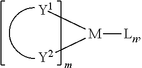

wherein M is a metal having an atomic weight greater than 40;

(Y¹-Y²) is a bidentate ligand, wherein Y¹ and Y² are independently selected from C, N, O, P and S; L is an auxiliary ligand; m is an integer from 1 to a maximum coordination number of the metal; and m+n is the maximum coordination number of the metal.

In one embodiment, (Y¹-Y²) is a 2-phenylpyridine derivative.

In another embodiment, (Y¹-Y²) is a carbene ligand.

In another embodiment, M can be selected from Ir, Pt, Os and Zn.

In another aspect, HOMO of the metal complex is greater than −5.5 ev (corresponding to a vacuum level).

Suitable examples of HIM/HTM compounds are listed as follows but not limited to:

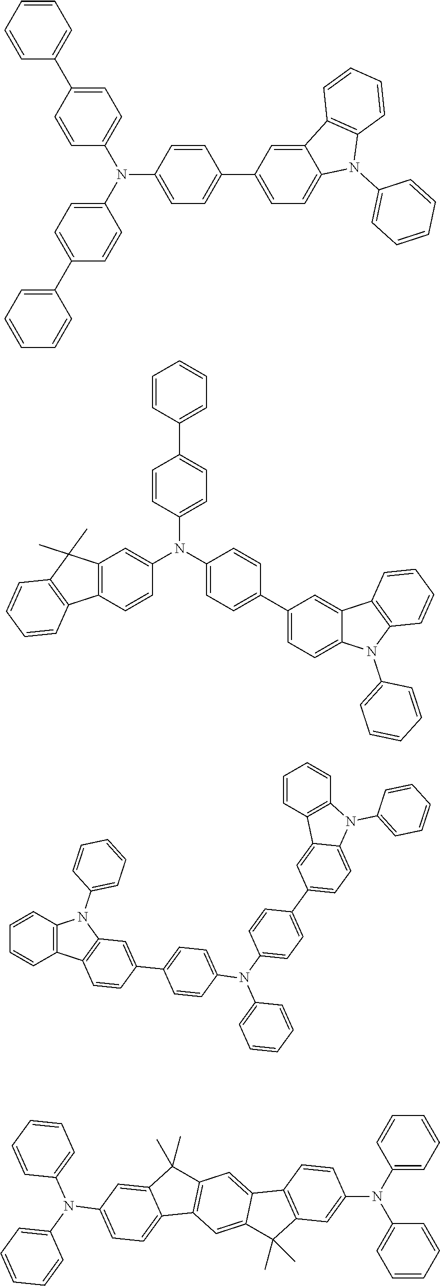 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc4c(c3)c3ccccc3n4-c3ccccc3)cc2)c2ccc(-c3ccc4c5ccccc5n(-c5ccccc5)c4c3)cc2)cc1 ; CC1(C)c2cc(N(c3ccccc3)c3ccccc3)ccc2-c2cc3c(cc21)-c1ccc(N(c2ccccc2)c2ccccc2)cc1C3(C)C]

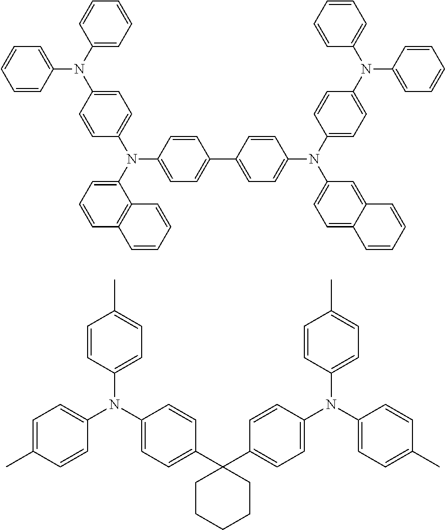

2. Triplet Host Material:

Examples of triplet host materials are not limited particularly, and any metal complexes or organic compounds can be used as host materials, only if the triplet energy thereof is higher than that of the emitter, particularly a triplet emitter or a phosphorescent emitter. Examples of metal complexes for use as triplet host include but are not limited to the following general structure:

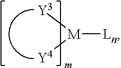

wherein M is a metal; (Y³-Y⁴) is a bidentate ligand, where Y³ and Y⁴ are independently selected from C, N, O, P and S; L is an auxiliary ligand; m is an integer from 1 to a maximum coordination number of the metal; and m+n is the maximum coordination number of the metal.

In one embodiment, a metal complex that can be used as the triplet host material may have a form selected from:

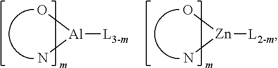

wherein (O—N) is a bidentate ligand, and the metal is coordinated with O and N atoms.

In an embodiment, M can be selected from Ir and Pt.

Examples of organic compounds for use as the triplet host material can be selected from, but not limited to, compounds having a cyclic aromatic hydrocarbon group such as benzene, biphenyl, triphenyl, benzo and fluorene; compounds having a heteroaromatic group such as dibenzothiophene, dibenzofuran, dibenzoselenophene, furan, thiophene, benzofuran, benzothiophene, benzoselenophen, carbazole, indolocarbazole, pyridineindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzoimidazole, indazole, oxazole, dibenzoxazole, benzisoxazole, benzothiazole, quinoline, isoquinoline, phthalazine (cinnoline), quinazoline, quinoxaline, naphthalene, phthalein, pteridine, xanthene, acridine, phenazine, phenothiazine, phenoxazine, benzofuropyridine, furopyridine, benzothienopyridine, thienopyridine, benzoselenophenopyridine and selenophene-benzodipyridine; and compounds containing groups having two to ten rings, which can be the same or different cyclic aromatic hydrocarbon groups or heteroaromatic groups linked directly or linked through for example at least one group as follows: an oxygen atom, a nitrogen atom, a sulfur atom, a silicon atom, a phosphorous atom, a boron atom, oxygen, nitrogen, sulfur, silicon, phosphorous, boron, a chain structural unit, and an aliphatic ring, wherein each Ar can be further substituted by a substituent group that can be selected from but not limited to hydrogen, alkyl, alkoxy, amino, alkenyl, alkynyl, aralkyl, heteroalkyl, aryl, and heteroaryl.

In one embodiment, the triplet host material can be selected from but not limited to compounds having at least one group as follows:

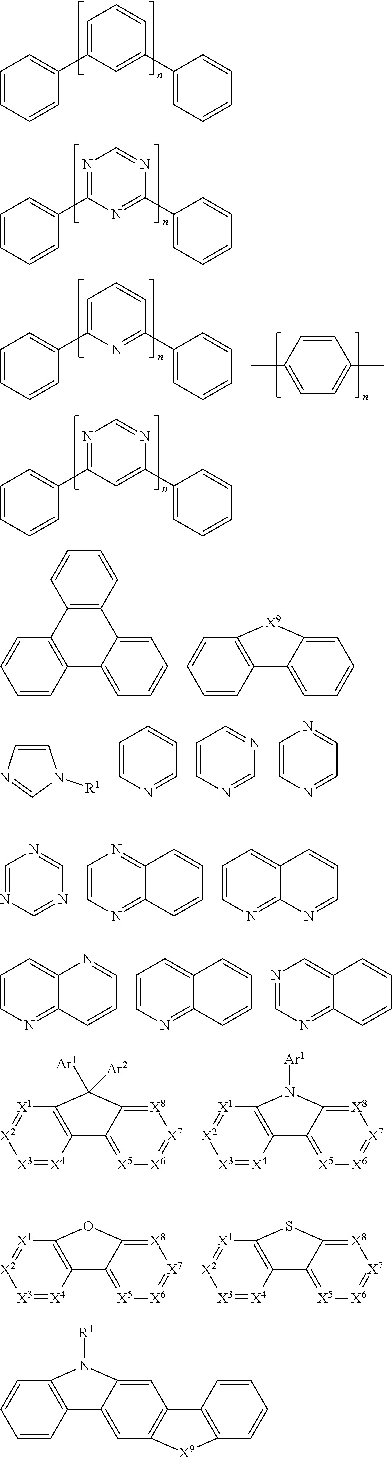

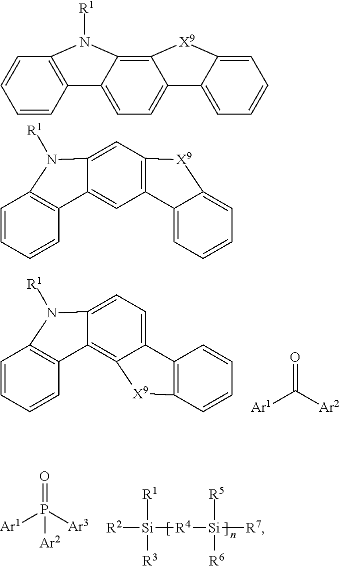

wherein R¹ to R⁷ can be independently selected from but not limited to hydrogen, alkyl, alkoxy, amino, alkenyl, alkynyl, aralkyl, heteroalkyl, aryl, and heteroaryl, and if R¹ to R⁷ are aryl or heteroaryl, definition of them are the same with Ar¹ and Ar²; n is an integer of 0-20; X¹ to X⁸ are selected from CH or N; and X⁹ is selected from CR¹R² or NR¹.

Suitable examples of the triplet host materials are listed as follows but not limited to:

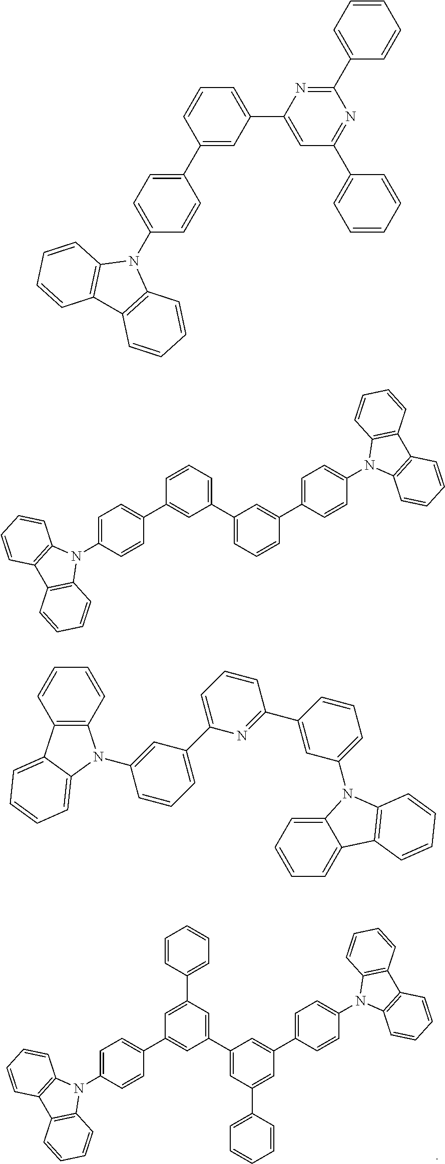

3. Singlet Host Material:

Examples of singlet host materials are not limited particularly, and any organic compounds can be used as host materials, only if the singlet state energy thereof is higher than that of the emitter, particularly a singlet emitter or a fluorescent emitter.

Examples of organic compounds for use as singlet host materials can be selected from, but not limited to, cyclic aromatic hydrocarbon compounds such as benzene, biphenyl, triphenyl, benzo, naphthalene, anthracene, phenalene, phenanthrene, fluorene, pyrene, chrysene, perylene, azulene; heteroaromatic compounds such as dibenzothiophene, dibenzofuran, dibenzoselenophene, furan, thiophene, benzofuran, benzothiophene, benzoselenophen, carbazole, indolocarbazole, pyridineindole, pyrrolodipyridine, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzoimidazole, indazole, indolizine, benzoxazole, benzisoxazole, benzothiazole, quinoline, isoquinoline, cinnoline, quinazoline, quinoxaline, naphthalene, phthalein, pteridine, xanthene, acridine, phenazine, phenothiazine, phenoxazine, benzofuropyridine, furodipyridine, benzothienopyridine, thienodipyridine, benzoselenophenopyridine and selenophenodipyridine; and a group having two to ten rings, which can be the same or different cyclic aromatic hydrocarbon groups or heteroaromatic groups linked directly or linked through for example at least one group as follows: an oxygen atom, a nitrogen atom, a sulfur atom, a silicon atom, a phosphorous atom, a boron atom, a chain structural unit, and an aliphatic ring.

In one embodiment, a singlet host material can be selected from but not limited to compounds having at least one group as follows:

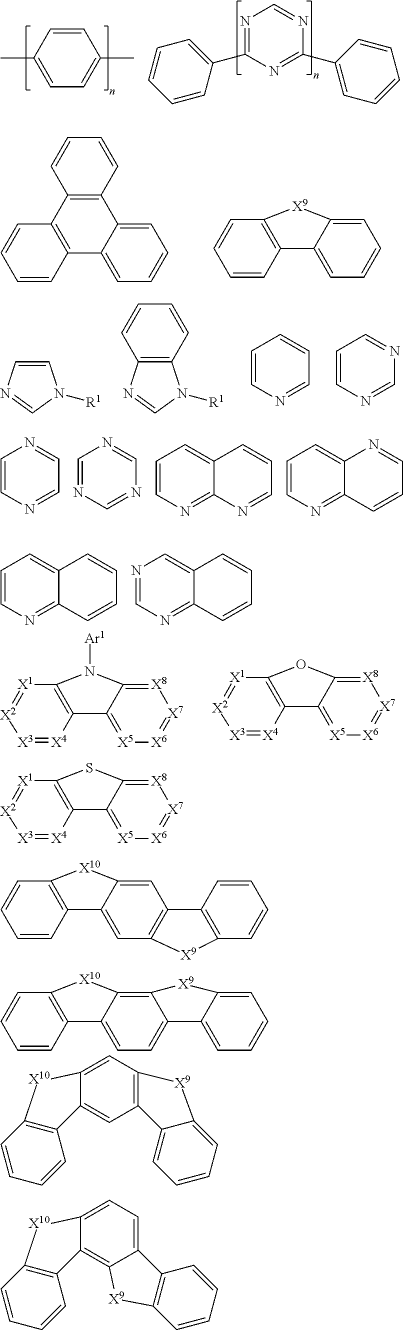

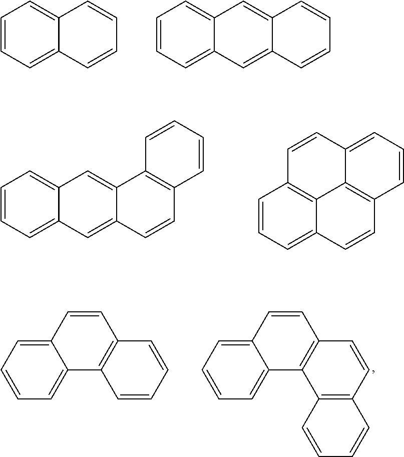

wherein R¹ can be independently selected from hydrogen, alkyl, alkoxy, amino, alkenyl, alkynyl, aralkyl, heteroalkyl, aryl and heteroaryl; Ar¹ can be but not limited to an aryl or heteroaryl, the definition thereof is the same as the Ar¹ of HTM as described above; n is an integer of 0 to 20; X¹ to X⁸ are selected from CH or N; and X⁹ and X¹⁰ are selected from CR¹R² or NR¹.

Some examples of anthryl singlet host materials are listed as follows but not limited to:

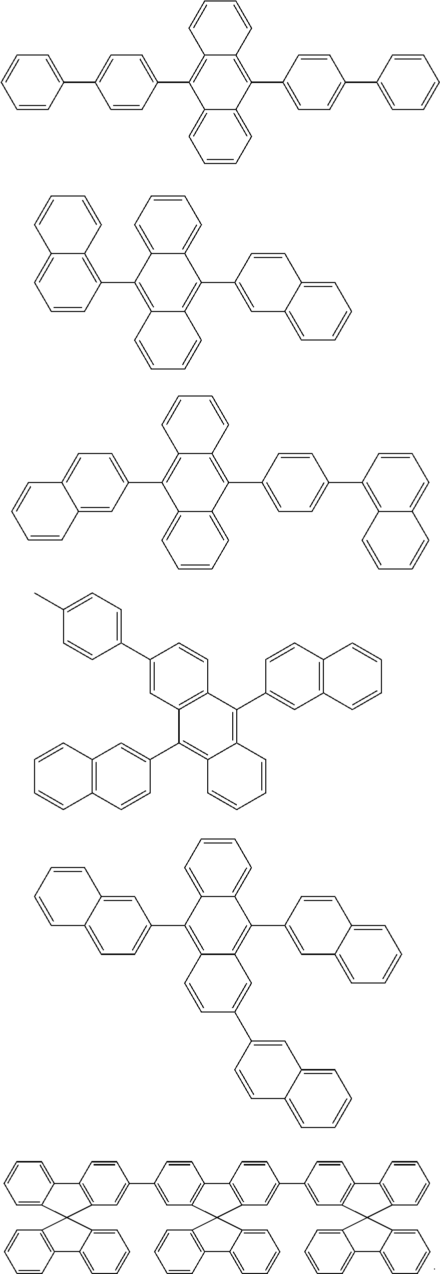

4. Singlet Emitter

A singlet emitter typically has a longer conjugate π electron system. Up to now, there are many examples such as styrylamine and its derivatives, and indenofluorene and its derivatives.

In one embodiment, a singlet emitter can be selected from but not limited to monostyrylamines, distyrylamines, tristyrylamines, tetrastyrylamines, styryl phosphines, styrylethers and arylamines.

The monostyrylamine refers to a compound having one unsubstituted or substituted styryl group and at least one amine (such as aromatic amine). The distyrylamine refers to a compound having two unsubstituted or substituted styryl groups and at least one amine (such as aromatic amine). The tristyrylamine refers to a compound having three unsubstituted or substituted styryl groups and at least one amine (such as aromatic amine). The tetrastyrylamine refers to a compound having four unsubstituted or substituted styryl groups and at least one amine (such as aromatic amine). In one embodiment styryl is distyryl, which can be substituted further. Correspondingly, definitions of phosphines and ethers are similar to the definition of amines. Arylamine or aromatic amine refers to a compound having three unsubstituted or substituted aromatic ring or heteroring systems linked directly to nitrogen. In one embodiment, at least one of these aromatic ring or heteroring systems is selected from fused ring systems, and for example, has at least 14 aromatic ring atoms. Examples include but are not limited to aromatic anthraceneamine, aromatic anthracenediamine, aromatic pyreneamine, aromatic pyrenediamine, aromatic chryseneamine and aromatic chrysenediamine. Aromatic anthraceneamine refers to a compound having one diarylamino group linked directly to anthracene, such as at position 9. Aromatic anthracenediamine refers to a compound having two diarylamino groups linked directly to anthracene, such as at positions 9 and 10. Definitions of aromatic pyreneamine, aromatic pyrenediamine, aromatic chryseneamine and aromatic chrysenediamine are similar to the above, wherein the diarylamino group can be linked to the pyrene at the position 1 or positions 1 and 6.

Embodiments of singlet emitter can be selected from indenofluorene-amine and indenofluorene-diamine, benzindenofluorene-amine and benzindenofluorene-diamine, dibenzindenofluorene-amine and dibenzindenofluorene-diamine, etc.

Other useful materials as singlet emitter include polycyclic aromatic hydrocarbon compounds, particularly derivatives of the following compounds but not limited to: anthracene such as 9,10-di(2-naphthanthracene), naphthalene, tetracene, xanthene, phenanthrene, pyrene (such as 2,5,8,11-tetra-t-butylpyrene), indenopyrene, phenylene such as (4,4′-di(9-ethyl-3-vinylcarbazole)-1,1′-biphenyl), diindenopyrene, decacyclene, coronene, fluorene, spirobifluorene, arylpyrene, arylene ethylene, cyclopentadiene such as tetraphenylcyclopentadiene, rubrene, coumarin, rhodamine, quinacridone, pyran such as 4(dicyanomethylene)-6-(4-p-dimethylaminostyryl-2-methyl)-4H-pyran (DCM), thiopyran, di(azinyl)iminoboron compounds, di(azinyl)methylene compounds, carbostyryl compounds, pentoxazone, benzoxazole, benzothiazole, benzimidazole and diketopyrrolopyrrole.

Suitable examples of singlet emitters are listed as follows but not limited to:

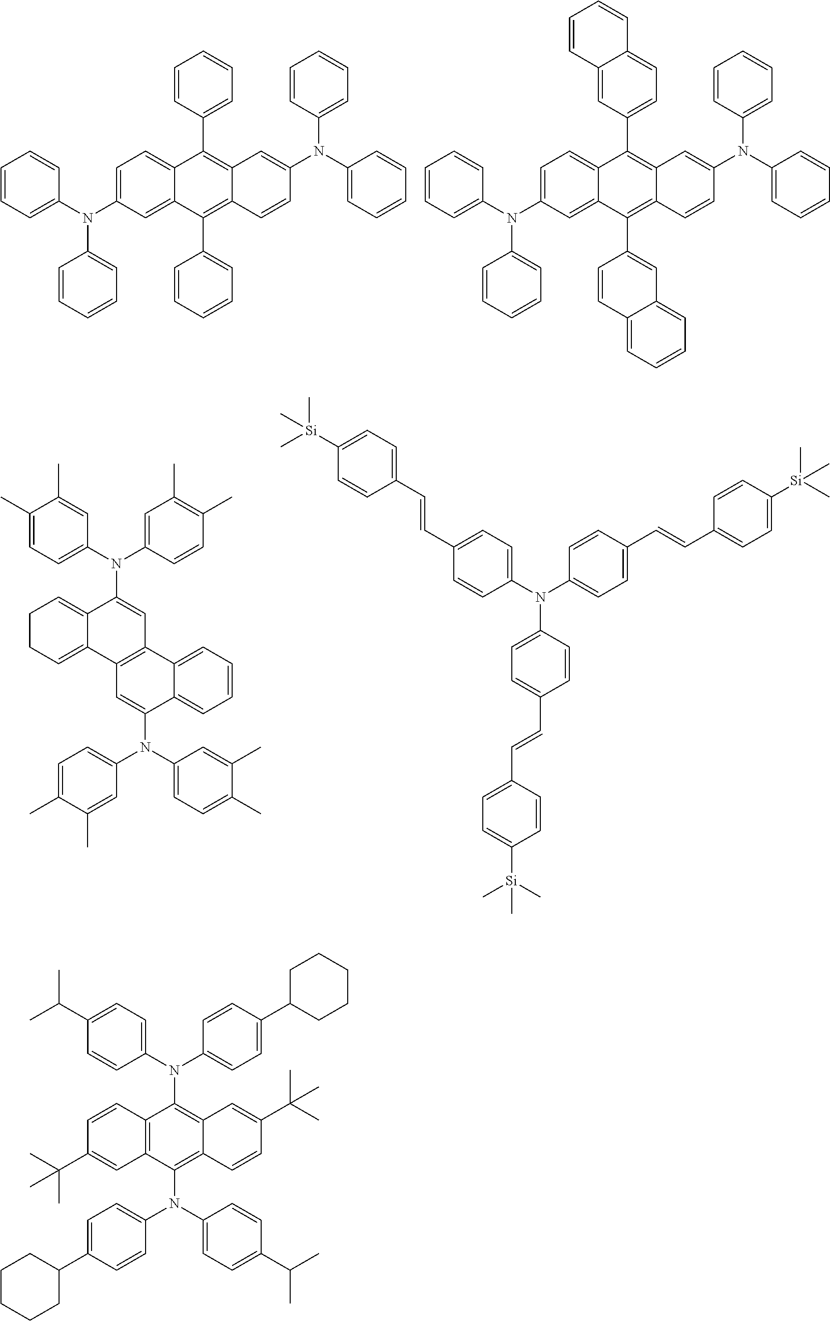

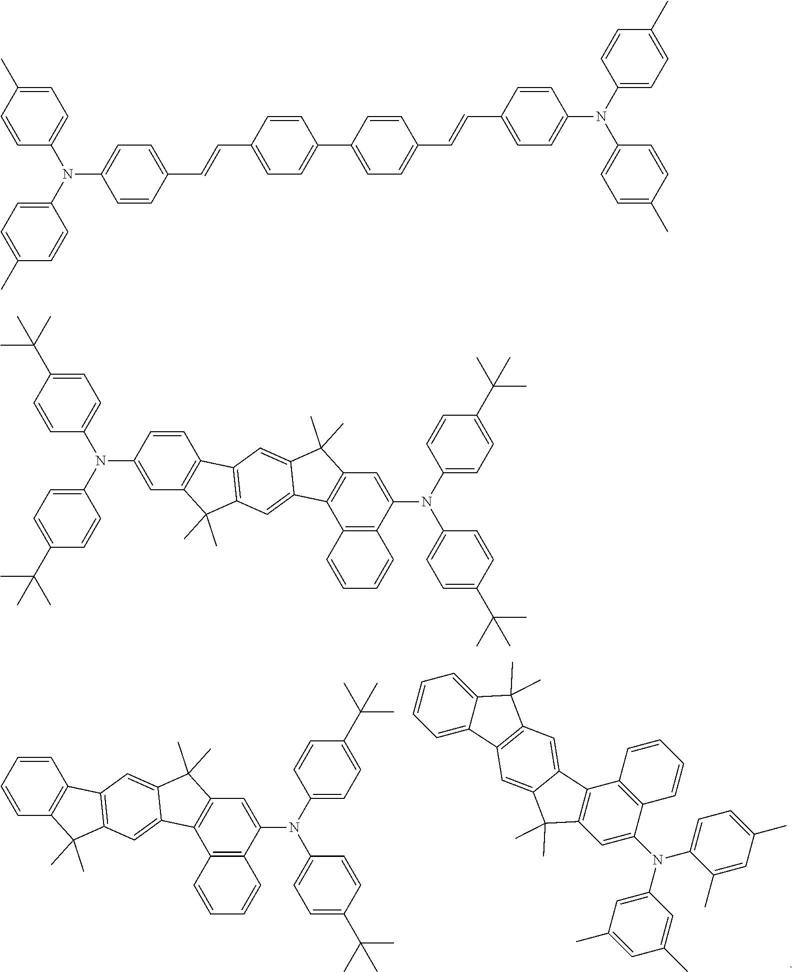

5. Thermally Activated Delayed Fluorescence Material (TADF):

A conventional organic fluorescent material only can emit light by 25% of singlet excitons produced by electrical excitation, so internal quantum efficiency of devices is lower (the highest is 25%). A phosphorescent material has an enhanced intersystem crossing due to strong spin-orbit coupling of a heavy atom center and can emit light efficiently by singlet excitons and triplet excitons produced by electrical excitation to obtain 100% internal quantum efficiency of devices. However, applications of phosphorescent materials in OLEDs are restricted due to high price, poor stability, serious roll-off of devices, etc. The thermally activated delayed fluorescence materials are the third generation of organic luminescent materials developed after the organic fluorescent materials and the organic phosphorescent materials. Typically, such materials have a small singlet-triplet energy difference (ΔEₛₜ) so that the triplet excitons can be converted to the singlet excitons via a reverse intersystem crossing to emit light. In this way, the singlet excitons and the triplet excitons produced by the electrical excitation can be fully utilized, and internal quantum efficiency of devices can achieve 100%.

The TADF materials should have a smaller singlet-triplet energy difference, typically ΔEₛₜ<0.3 eV, in one embodiment ΔEₛₜ<0.2 eV, in another embodiment ΔEₛₜ<0.1 eV and in yet another embodiment ΔEₛₜ<0.05 eV. In one embodiment, TADF has preferred fluorescent quantum efficiency.

Suitable examples of the TADF luminescent materials are listed as follows but not limited to:

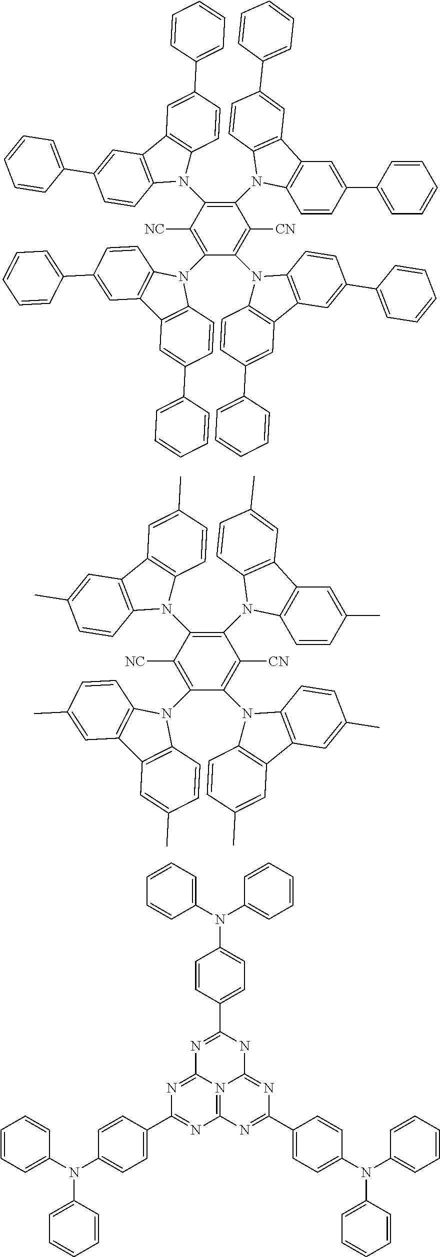

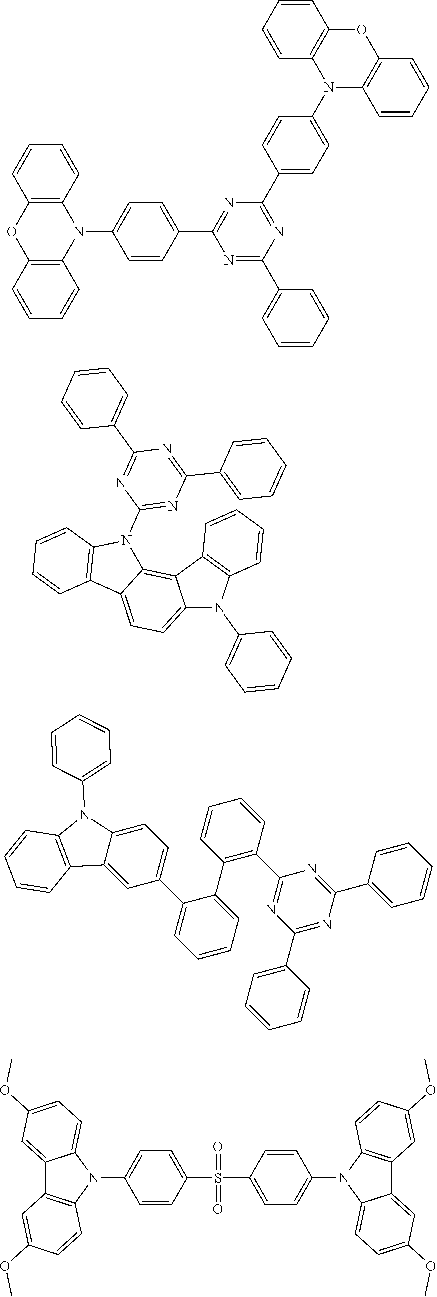 [SMILES: c1ccc(-c2nc(-c3ccc(N4c5ccccc5Oc5ccccc54)cc3)nc(-c3ccc(N4c5ccccc5Oc5ccccc54)cc3)n2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccccc3-c3ccccc3-c3ccc4c(c3)c3ccccc3n4-c3ccccc3)n2)cc1 ; COc1ccc2c(c1)c1cc(OC)ccc1n2-c1ccc(S(=O)(=O)c2ccc(-n3c4ccc(OC)cc4c4cc(OC)ccc43)cc2)cc1]

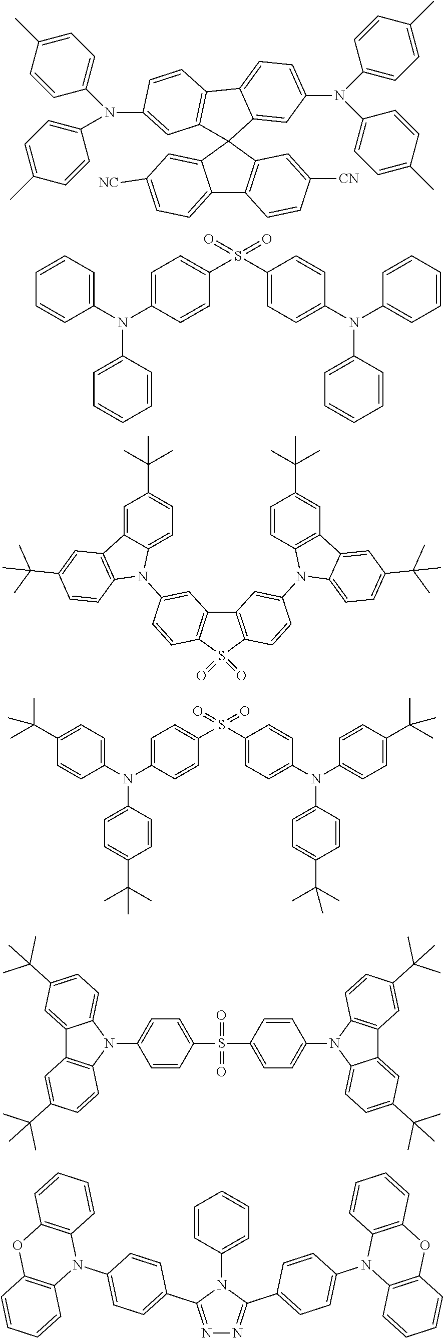

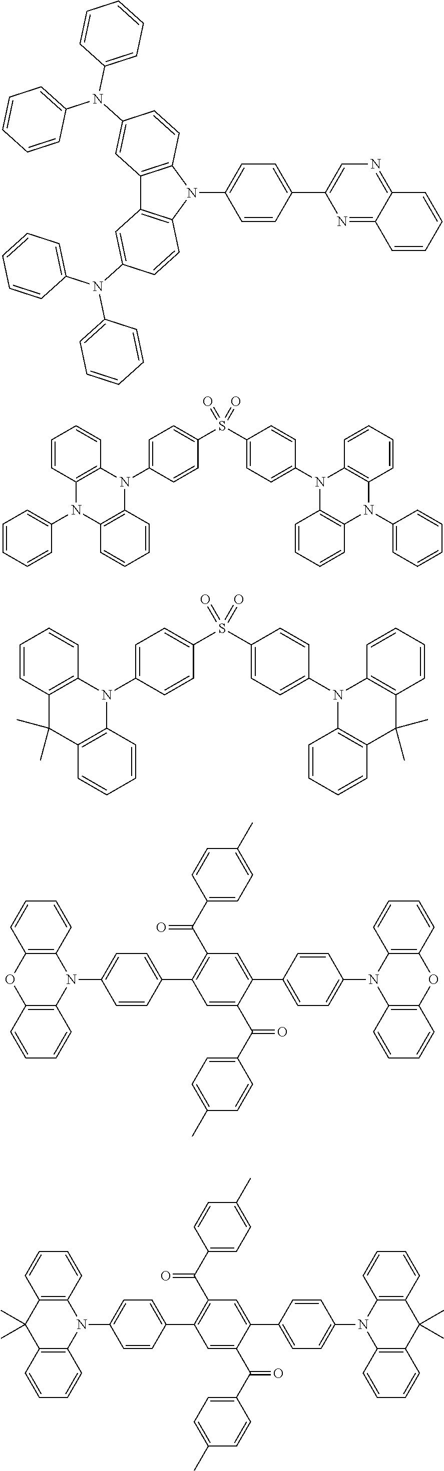

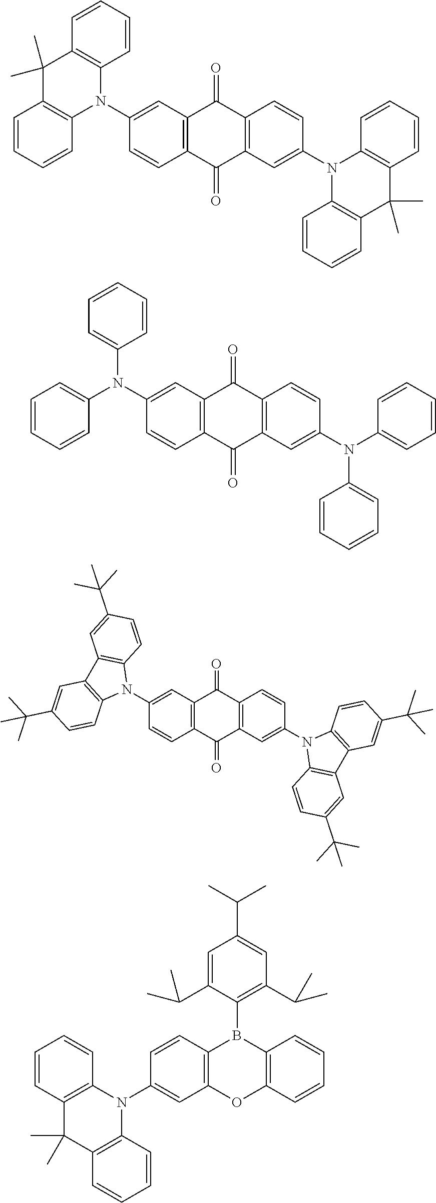

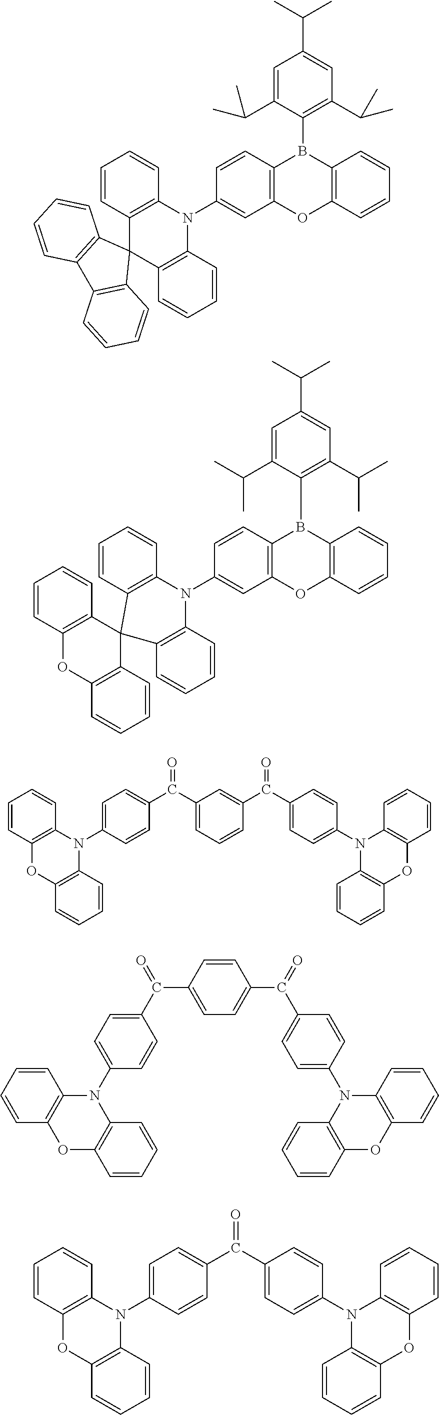 [SMILES: CC(C)c1cc(C(C)C)c(B2c3ccccc3Oc3cc(N4c5ccccc5C5(c6ccccc6-c6ccccc65)c5ccccc54)ccc32)c(C(C)C)c1 ; CC(C)c1cc(C(C)C)c(B2c3ccccc3Oc3cc(N4c5ccccc5C5(c6ccccc6Oc6ccccc65)c5ccccc54)ccc32)c(C(C)C)c1 ; O=C(c1ccc(N2c3ccccc3Oc3ccccc32)cc1)c1cccc(C(=O)c2ccc(N3c4ccccc4Oc4ccccc43)cc2)c1 ; O=C(c1ccc(C(=O)c2ccc(N3c4ccccc4Oc4ccccc43)cc2)cc1)c1ccc(N2c3ccccc3Oc3ccccc32)cc1 ; O=C(c1ccc(N2c3ccccc3Oc3ccccc32)cc1)c1ccc(N2c3ccccc3Oc3ccccc32)cc1]

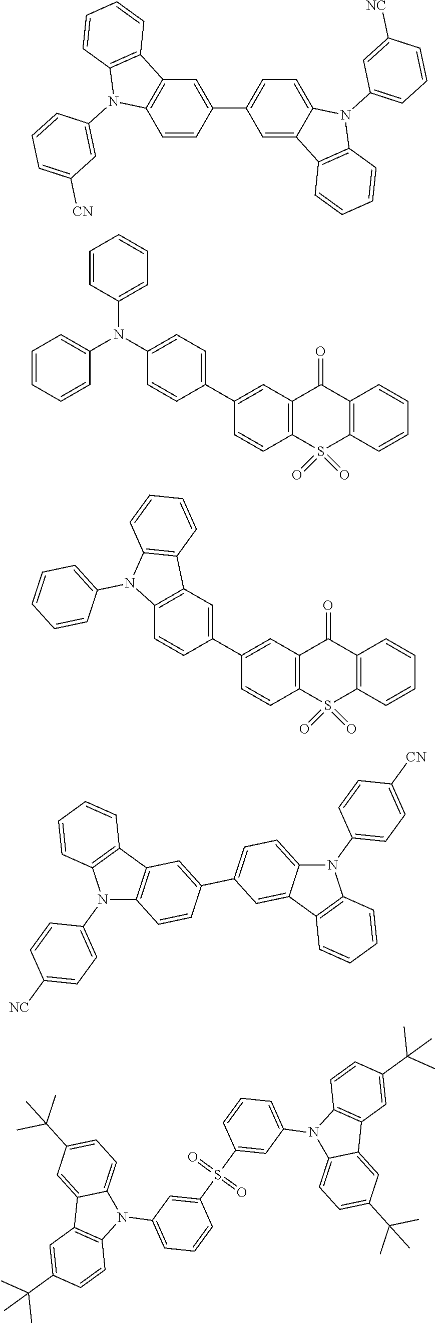

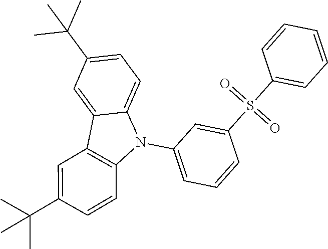 [SMILES: CC(C)(C)c1ccc2c(c1)c1cc(C(C)(C)C)ccc1n2-c1cccc(S(=O)(=O)c2ccccc2)c1]

6. Triplet Emitter:

A triplet emitter is also known as a phosphorescent emitter. In one embodiment, a triplet emitter is a metal complex of formula M(L)ₙ, wherein M is a metal atom; for each occurrence, L is a same or different organic ligand bonded to or coordinated with the metal atom M at one or more positions, and n is an integer larger than 1, such as 1, 2, 3, 4, 5 or 6. Optionally, such metal complex is linked to polymer at one or more positions, such as via an organic ligand.

In one embodiment, the metal atom M can be selected from but not limited to transition metal elements, lanthanide elements, or actinide elements, such as, Ir, Pt, Pd, Au, Rh, Ru, Os, Sm, Eu, Gd, Tb, Dy, Re, Cu or Ag, and in some embodiment can be Os, Ir, Ru, Rh, Re, Pd or Pt.

In one embodiment, the triplet emitter may include a chelating ligand, i.e., a ligand coordinated with metal at at least two positions. In one embodiment, the triplet emitter includes two or three of same or different bidentate or polydentate ligands. A chelating ligand is beneficial to improve the stability of metal complex.

Examples of organic ligands can be selected from but not limited to phenylpyridine derivatives, 7,8-benzoquinoline derivatives, 2-(2-thienyl)pyridine derivatives, 2-(1-naphthyl) pyridine derivatives, or 2-phenylquinoline derivatives. All of these organic ligands can be substituted, for example, by fluoro- or trifluoromethyl. An auxiliary ligand can be selected from acetylacetonate or picric acid.

In one embodiment, a metal complex as the triplet emitter has the following form:

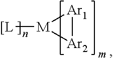

wherein M is a metal selected from transition metal elements, lanthanide elements, or actinide elements;

for each occurrence, Ar¹ can be a same or different cyclic group having at least one donor atom, i.e. one atom of lone pair electrons such as N or P, via which the cyclic group is coordinated with the metal; and for each occurrence, Ar² can be a same or different cyclic group having at least one carbon atom, via which the cyclic group is linked to the metal. Ar¹ and Ar² are linked via a covalent bond, and each of them can carry one or more substituent groups or they also can be linked again via a substituent group. For each occurrence, L can be a same or different auxiliary ligand, such as a bidentate chelating ligand, and in one embodiment is a monoanion bidentate chelating ligand; m is 1, 2 or 3, in some embodiments is 2 or 3, and in one embodiment is 3; n is 0, 1, or 2, in some embodiments is 0 or 1, and in one embodiment is 0.

Suitable examples of the triplet emitter are as listed but not limited to:

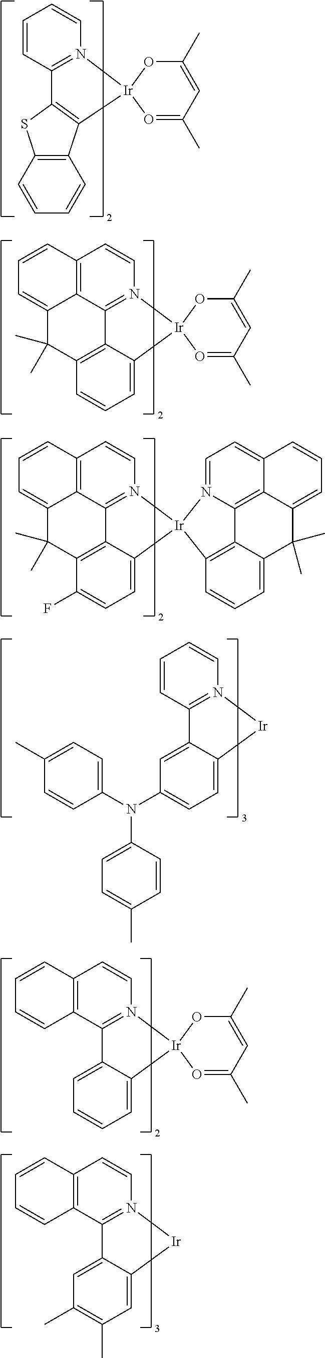

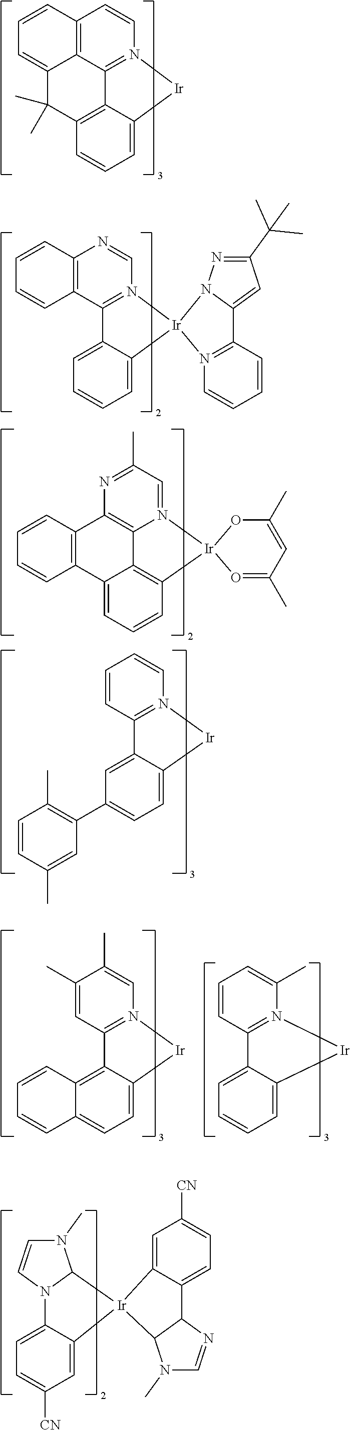

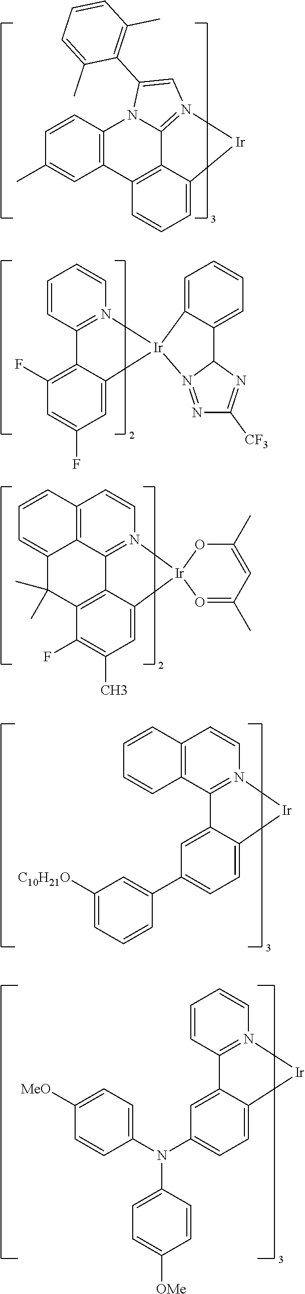

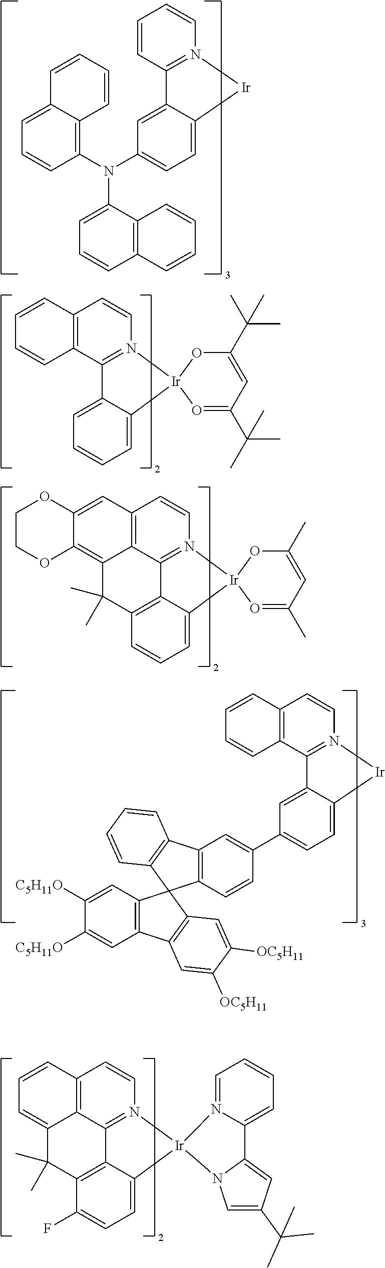

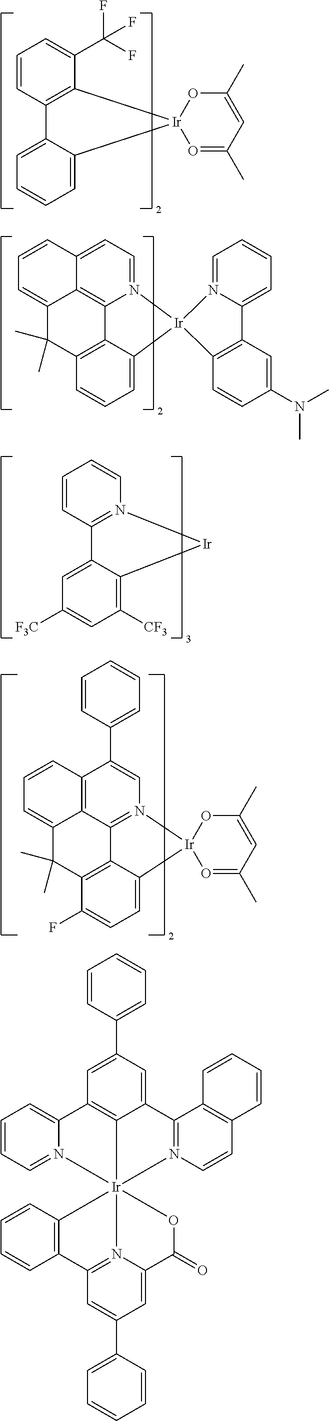

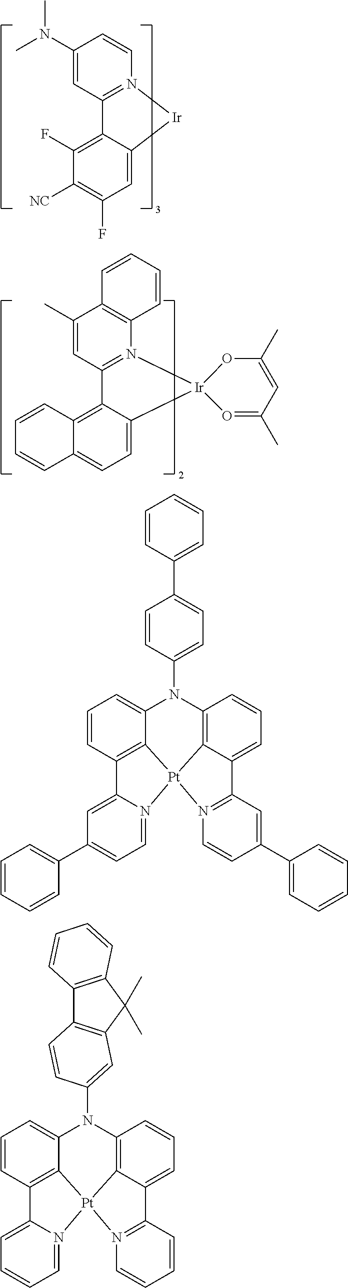

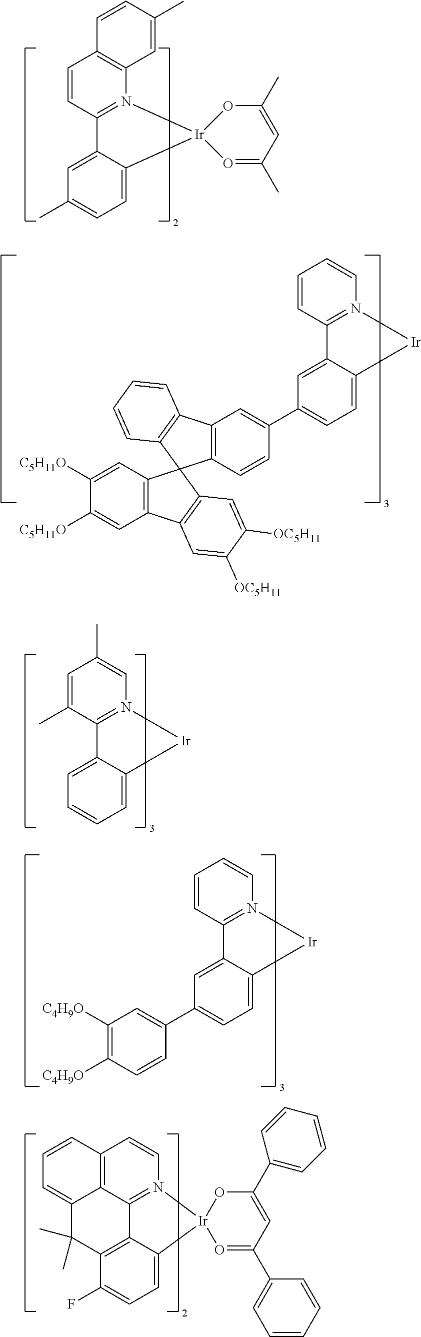

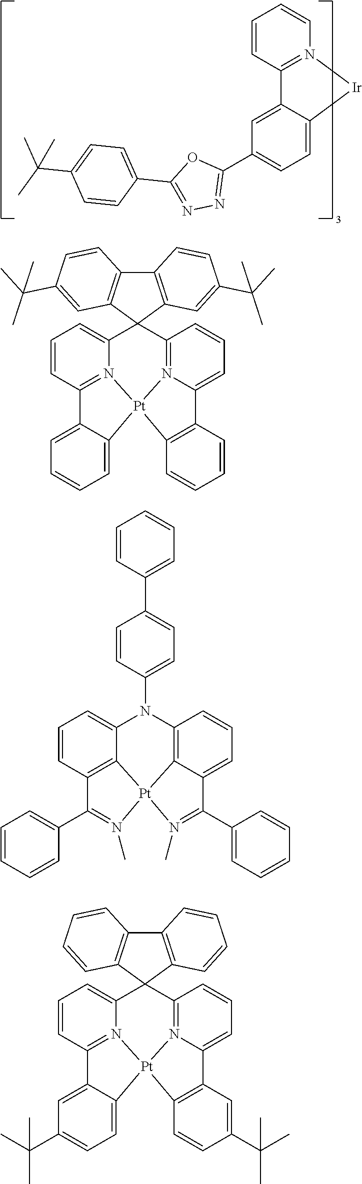

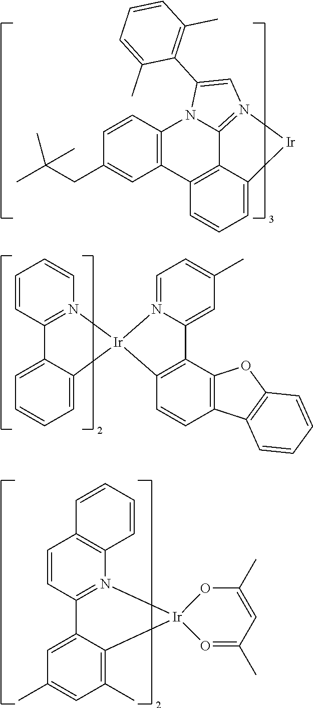

In another embodiment, the functional material included in the formulation for printed electronics of the present disclosure can be a polymer material.

Typically, the small molecular organic functional material described above can include HIM, HTM, ETM, EIM, host material, fluorescence emitter, phosphorescent emitter, TADF and so on, and any of them can be included in a polymer as a repeating unit.

In one embodiment, a suitable polymer for the present disclosure can be a conjugated polymer. Typically, the conjugated polymer has the following formula:

BₓA_{y} Chemical Formula 1

wherein when B and A appear many times, they can independently select a same or different structural unit.

B also known as a backbone unit is a π-conjugated structural unit with a greater energy gap, and selected from monocyclic or polycyclic aryl or heteroaryl, such as benzene, biphenylene, naphthalene, anthracene, phenanthrene, dihydrophenanthrene, 9,10-dihydrophenanthrene, fluorene, difluorene, spirobifluorene, p-phenyl acetylene, trans-indenofluorene, cis-indeno, dibenzo-indenofluorene, indenonaphthalene and derivatives thereof.

A also known as a functional unit is a π-conjugated structural unit with a smaller energy gap, and in accordance with different function requirements, can be selected from but not limited to the structural units of the hole injection or transport material (HIM/HTM), the electron injection or transport material (EIM/ETM), the host material (Host), the singlet emitter (fluorescence emitter) and the triplet emitter (phosphorescent emitter) described above.

Moreover, x and y are larger than 0, and x+y=1.

In some embodiments, the functional material included in the formulation for printed electronics of the present disclosure is polymer HTM.

In one embodiment, the polymer HTM is a homopolymer, and the homopolymer can be selected from polythiophene, polypyrrole, polyaniline, polybiphenyltriarylamine, polyvinylcarbazole, and derivatives thereof.

In another embodiment, the polymer HTM is a conjugated polymer represented by Chemical Formula 1,

wherein A is a functional group having hole transport ability, and can be identically or differently selected from the structural units of the hole injection or transport material (HIM/HTM) described above. In one embodiment, A is selected from amine, biphenyltriarylamine, thiophene, thiophthene such as dithienothiophene and thiophthene, pyrrole, aniline, carbazole, indenocarbazole, indolocarbazole, pentacene, phthalocyanine, porphyrin and derivatives thereof.

Moreover, x and y are larger than 0, and x+y=1, typically y≥0.10, in one embodiment y≥0.15, in another embodiment y≥0.20, and in yet another embodiment x=y=0.5.

Suitable examples of the conjugated polymer as HTM are listed below but not limited to:

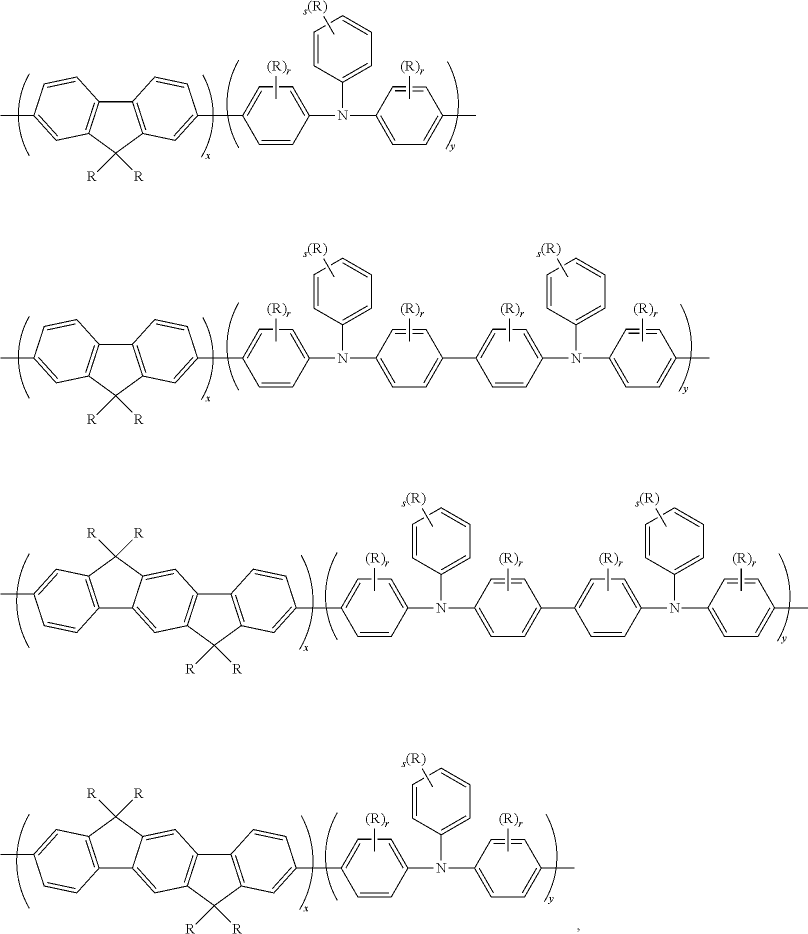

wherein each R is independently selected from H, straight chain alkyl, straight chain alkoxy, or straight chain thioalkoxy each containing 1 to 20 carbon atoms; branched or cyclic alkyl, branched or cyclic alkoxy, branched or cyclic thioalkoxy, or branched or cyclic silyl each containing 3 to 20 carbon atoms; C₁-C₂₀ substituted keto, C₂-C₂₀ alkoxycarbonyl, C₇-C₂₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 40-membered aromatic or heteroaromatic rings, or 5- to 40-membered aryloxy or heteroaryloxy, wherein one or more of R can exist independently or can form a monocyclic or a polycyclic aliphatic or aromatic ring system with each other and/or with a ring linked to the functional groups.

Moreover, r is 0, 1, 2, 3 or 4;

s is 0, 1, 2, 3, 4 or 5;

x and y are larger than 0, and x+y=1, typically y≥0.10, in one embodiment y≥0.15, in another embodiment y≥0.20, and in yet another embodiment x=y=0.5.

Another type of organic functional materials can be polymer having electron transport ability, including conjugated polymer and non-conjugated polymer.

An embodiment of a polymer ETM is homopolymer, selected from polyphenanthrene, polyphenanthroline, polyindenofluorene, polyspirobifluorene, polyfluorene and derivatives thereof.

An embodiment of a polymer ETM can be a conjugated polymer represented by Chemical Formula 1, and when A appears many times, A can be a same or different independently selected form as follows:

A is a functional group having electron transport ability, and selected from tri(8-hydroxyquinoline)aluminum (AlQ3), benzene, biphenylene, naphthalene, anthracene, phenanthrene, dihydrophenanthrene, fluorene, bifluorene, spirobifluorene, p-phenyl acetylene, pyrene, pyreneperylene, 9,10-dihydrophenanthrene, phenazine, phenanthroline, trans-indenofluorene, cis-indenofluorene, dibenzo-indenofluorene, indenonaphthalene, benzoanthracene and derivatives thereof.

Moreover, x and y are larger than 0, and x+y=1, typically y≥0.10, in one embodiment y≥0.15, in another embodiment y≥0.20, and in yet another embodiment x=y=0.5.

In another embodiment, the functional material included in the formulation for printed electronics of the present disclosure is a luminescent polymer.

In an embodiment, the luminescent polymer is a conjugated polymer having the following formula,

BₓA₁_{y}A₂_{z} Chemical Formula 2

wherein B is defined the same with that in Chemical Formula 1.

A1 is a functional group having hole or electron transport ability and can be selected from but not limited to the structural units of the above-mentioned hole injection or transport material (HIM/HTM) or electron injection or transport material (EIM/ETM).

A2 is a functional group having a light-emitting function and can be selected from but not limited to the structural units of the above-mentioned singlet emitter (fluorescence emitter) or triplet emitter (phosphorescent emitter).

Moreover, x, y and z are larger than 0, and x+y+z=1.

In another embodiment, a suitable polymer for the present disclosure can be a non-conjugated polymer, which can be a polymer having all functional groups at its side chains while its main chain is non-conjugated. Examples thereof can be selected without limitation from non-conjugated polymers used as phosphorescent host or phosphorescent light-emitting materials, and non-conjugated polymers used as fluorescent luminescent materials. Furthermore, the non-conjugated polymer also can be a polymer having conjugated functional units of the main chain linked through non-conjugated linking units.

The present disclosure further relates to a method for forming a film containing a functional material through a printing or coating process, wherein any one of the formulations described above is coated on a substrate through a printing or coating process, which can be selected without limitation from ink-jet printing, nozzle printing, typographic printing, screen printing, dip coating, spin coating, blade coating, roller printing, torsion roller printing, lithographic printing, flexographic printing, rotary printing, spray coating, brush coating, pad printing, slot die coating, etc.

In an embodiment, the film containing the functional material is formed through ink-jet printing. An ink-jet printer capable of printing the ink of the present disclosure is available on the market, and includes drop-on-demand printheads. These printers may be commercially avaible from Fujifilm Dimatix (Lebanon, N.H.), Trident International (Brookfield, Conn.), Epson (Torrance, Calif.), Hitachi Data systems Corporation (Santa Clara, Calif.), Xaar PLC (Cambridge, United Kingdom), and Idanit Technologies, Limited (Rishon Le Zion, Isreal). For example, Dimatix Materials Printer DMP-3000 (Fujifilm) can be used in the present disclosure.

The present disclosure further relates to an electronic device having one or more layers of functional film, at least one of which is formed from the printing ink formulation of the present disclosure, especially through a printing or coating process.

A suitable electronic device may be selected from but not limited to a quantum dot light emitting diode (QLED), a quantum dot photovoltaic cell (QPV), a quantum dot light emitting electrochemical cell (QLEEC), a quantum dot field effect transistor (QFET), a quantum dot light emitting field effect transistor, a quantum dot laser, a quantum dot sensor, an organic light emitting diode (OLED), an organic photovoltaic cell (OPV), an organic light emitting electrochemical cell (OLEEC), an organic field effect transistor (OFET), an organic light emitting field effect transistor, an organic laser, an organic sensor, etc.

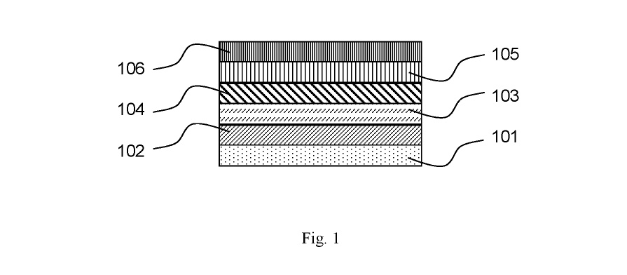

In an embodiment, the above electronic device is an electroluminescent device or a photovoltaic cell, as shown in FIG. 1, which includes a substrate 101, an anode 102, at least one light emitting layer or light-absorbing layer 104, and a cathode 106. Following description only takes the electroluminescent device as an example.

The substrate 101 can be opaque or transparent. A transparent substrate can be used to manufacture a transparent light emitting device. The substrate can be rigid or elastic. The substrate can be plastic, metal, semiconductor wafer or glass. In one embodiment, the substrate has a smooth surface. A substrate with a defect-free surface is a particularly desirable choice. In an embodiment, the substrate can be selected from a polymer film or a plastic, glass transition temperature Tg of which is 150° C. or above, in another embodiment is higher than 200° C., in yet another embodiment is higher than 250° C., and in yet another embodiment is higher than 300° C. Suitable examples of the substrate include but are not limited to poly(ethylene terephthalate) (PET) and polyethyleneglycol(2, 6-naphthalene)) (PEN).

The anode 102 can include conducting metal or metal oxide, or conducting polymer. The anode can inject hole easily to the HIL or the HTL or the light emitting layer. In one embodiment, the absolute value of difference between the work function of the anode and the HOMO level or the valence band level of the p-type semiconductor material as HIL or HTL is smaller than 0.5 ev, in another embodiment is smaller than 0.3 ev, and in yet another embodiment is smaller than 0.2 ev. Examples of the anode material include but not limited to Al, Cu, Au, Ag, Mg, Fe, Co, Ni, Mn, Pd, Pt, ITO, Al-doped zinc oxide (AZO), etc. Other suitable anode materials are known, and a person having general technical knowledge in the art can select and use them easily. The anode material can be deposited by any suitable technology, such as by a suitable physical vapor deposition method including radio-frequency magnetron sputtering, vacuum thermal evaporation, e-beam, etc.

In some embodiments, the anode is patterned. A patterned ITO conductive substrate available on the market can be utilized to manufacture the device of the present disclosure.

The cathode 106 can include conducting metal or metal oxide. The cathode can inject electron easily to the EIL or the ETL or the light emitting layer. In one embodiment, the absolute value of difference between the work function of the cathode and the LUMO level or the conduction band level of the n-type semiconductor material as EIL or ETL or HBL is smaller than 0.5 ev, in another embodiment is smaller than 0.3 ev, and in yet another embodiment is smaller than 0.2 ev. In principle, all of the materials for use in a cathode of OLED can be used as the cathode material of the device in the present disclosure. Examples of the cathode material include but are not limited to Al, Au, Ag, Ca, Ba, Mg, LiF/Al, MgAg alloy, BaF₂/Al, Cu, Fe, Co, Ni, Mn, Pd, Pt, ITO, etc. The cathode material can be deposited by any suitable technology, such as by a suitable physical vapor deposition method including radio-frequency magnetron sputtering, vacuum thermal evaporation, e-beam, etc.

The light emitting layer 104 can at least include one layer of luminescent material in a thickness between 2 nm and 200 nm. In one embodiment, the light emitting device of the present disclosure includes a light emitting layer printed from the printing ink of the present disclosure, wherein the printing ink includes at least one luminescent material describe above, particularly the quantum dots or the organic functional materials.

In an embodiment, the light emitting device of the present disclosure further includes a hole injection layer (HIL) or a hole transport layer (HTL) 103 including the organic HTM or the inorganic p-type material described above. In one embodiment, the HIL or the HTL can be printed from the printing ink of the present disclosure, wherein the printing ink includes a functional material having hole transport ability, particularly the quantum dots or the organic HTM material.

In another embodiment, the light emitting device of the present disclosure further includes an electron injection layer (EIL) or an electron transport layer (ETL) 105 including the organic ETM or the inorganic n-type material described above. In some embodiments, the EIL or the ETL can be printed from the printing ink of the present disclosure, wherein the printing ink includes a functional material having electron transport ability, particularly the quantum dots or the organic ETM.

The present disclosure further relates to a use of the light emitting device of the present disclosure on various occasions, including without limitation various display devices, backlight units, lighting sources, etc.

The present disclosure will be described below with reference to some embodiments, but the present disclosure is not limited to the following embodiments. It should be understood that the appended claims summarized the scope of the present disclosure. Under the guiding of the concept of the present disclosure, those skilled in the art should be aware that certain changes to the various embodiments of the present disclosure should be covered by the spirit and the scope of the claims of the present disclosure.

### EXAMPLES

### Example 1: Preparation of Quantum Dots as a Blue Emitter (CdZnS/ZnS)

A first solution for use is prepared through adding 0.0512 g of S and 2.4 mL of ODE in a single-neck flask with a capacity of 25 mL, and heating to 80° C. in an oil bath to dissolve S. A second solution for use is prepared through adding 0.1280 g of S and 5 mL of OA in a single-neck flask with a capacity of 25 mL, and heating to 90° C. in an oil bath to dissolve S. After that, 0.1028 g of CdO, 1.4680 g of zinc acetate and 5.6 mL of OA are added to a three-neck flask with a capacity of 50 mL, which is subsequently placed in a heating jacket with a capacity of 150 mL in a state that the necks at both sides are blocked by rubber stoppers and the upper side is connected to a condenser, and the condenser is connected to a double manifold at the other side. The three-neck flask is heated to 150° C., vacuumized for 40 min, and then purged with nitrogen gas. Then, 12 mL of ODE is injected into the three-neck flask by an injector. When the mixture in the three-neck flask is heated to 310° C., 1.92 mL of the first solution is injected quickly into the three-neck flask via an injector, and the time is counted up to 12 min. Once reaching 12 min, 4 mL of the second solution is dropwise added to the three-neck flask by an injector at a speed of about 0.5 mL/min. The reaction is stopped after 3 h, and the three-neck flask is placed in water immediately to be cooled to 150° C.

An excessive amount of n-hexane is added to the three-neck flask. The liquid in the three-neck flask is transferred to several centrifuge tubes with a capacity of 10 mL and subsequently treated by performing centrifugation and removing of the lower precipitation for three times. The liquid after post treatment 1 is added with acetone until precipitate occurs, after which centrifugation is performed and the supernatant liquid is removed to obtain the precipitate. The precipitate is dissolved with n-hexane again and then added with acetone until precipitate occurs, after which centrifugation is performed and the supernatant liquid is removed to obtain the precipitate, and the above steps are repeated for three times. Finally, the precipitate is dissolved with toluene and then transferred to a glass vessel for storage.

### Example 2: Preparation of Quantum Dots as a Green Emitter (CdZnSeS/ZnS)

A first solution for use is prepared through adding 0.0079 g of Se and 0.1122 g of S in a single-neck flask with a capacity of 25 mL, metering 2 mL of TOP, purging nitrogen gas and stirring. After that, 0.0128 g of CdO, 0.3670 g of zinc acetate and 2.5 mL of OA are added to a three-neck flask with a capacity of 25 mL, of which the necks at both sides are blocked by rubber stoppers and the upper side is connected to a condenser that is connected to a double manifold at the other side. The three-neck flask is subsequently placed in a heating jacket with a capacity of 50 mL and subjected to the following steps of being vacuumized, purged with nitrogen gas, heated to 150° C., vacuumized for 30 min, injected with 7.5 mL of ODE, heated again to 300° C., injected quickly with 1 mL of the first solution, and kept for 10 min. Once reaching 10 min, the reaction is stopped immediately, and the three-neck flask is placed in water for cooling.

Afterwards, 5 mL of n-hexane is added to the three-neck flask. The mixed liquid is transferred to several centrifuge tubes of 10 mL and added with acetone until precipitate occurs, after which centrifugation is performed and the supernatant liquid is removed to obtain the precipitate. The precipitate is dissolved with n-hexane and then added with acetone until precipitate occurs, after which centrifugation is performed, and the above steps are repeated for three times. Finally, the precipitate is dissolved with a small amount of toluene and then transferred to a glass vessel for storage.

### Example 3: Preparation of Quantum Dots as a Red Emitter (CdSe/CdS/ZnS)

A CdSe core of about 3.5 nm is prepared through the steps of adding 1 mmol of CdO, 4 mmol of OA and 20 ml of ODE to a three-neck flask with a capacity of 100 ml, purging nitrogen gas and heating to 300° C. to obtain Cd(OA)₂ precursor; at this temperature, injecting quickly 0.25 mL of TOP with dissolved 0.25 mmol of Se powder; and allowing the reaction solution to react at this temperature for 90 sec to grow the CdSe core of about 3.5 nm. Afterwards, a CdS shell in a thickness of about 1 nm is formed through adding dropwise 0.75 mmol of octanethiol to the reaction solution at 300° C. and reacting for 30 min to grow the CdS shell. After that, the reaction solution is added dropwise with 4 mmol of Zn(OA)₂ and 2 mL of TBP with dissolved 4 mmol of S powder to grow a ZnS shell (about 1 nm). After reacting for 10 min, the reaction solution is cooled to the room temperature.

Afterwards, 5 mL of n-hexane is added to the three-neck flask. The mixed liquid is transferred to several centrifuge tubes of 10 mL and added with acetone until precipitate occurs, after which centrifugation is performed and the supernatant liquid is removed to obtain the precipitate. The precipitate is dissolved with n-hexane and then added with acetone until precipitate occurs, after which centrifugation is performed, and the above steps are repeated for three times. Finally, the precipitate is dissolved with a small amount of toluene and then transferred to a glass vessel for storage.

### Example 4: Preparation of ZnO Nanoparticles

A first solution is prepared by adding 1.475 g of zinc acetate in 62.5 mL of methanol. A second solution is prepared by dissolving 0.74 g of KOH in 32.5 mL of methanol. The first solution is heated to 60° C. and stirred intensively. The second solution is dropwise added to the first solution by a sample injector, after which the mixed solution system is continuously stirred at 60° C. for 2 h. The heating source is removed and the solution system is kept quietly for 2 h. The reaction solution is washed by centrifugation for at least three times under the centrifugal condition of 4500 rpm, 5 min, and the white solid obtained finally is ZnO nanoparticles having a diameter of about 3 nm.

The boiling point, surface tension and viscosity parameters of a part of the heteroaromatic solvents utilized in the examples of the present disclosure are listed below:

| | | Boil- | Surface | Visco- |
|---|---|---|---|---|
| | | ing | Tension | sity |
| | Structural | Point | @RT | @RT |
| Name | Formula | (° C.) | (dyne/cm) | (cPs) |
| quinoline | 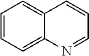 | 237 | 45 | 4.3 |
| isoquinoline | 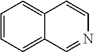 | 243 | 46 | 3.3 |

The boiling point, surface tension and viscosity parameters of another kind of solvent utilized in the examples of the present disclosure are listed below:

| | | | | |
|---|---|---|---|---|
| 3-phenoxy- toluene | 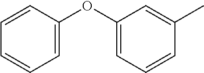 | 272 | 37.4 | 5 |
| dodecyl- benzene | 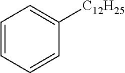 | 331 | 30.12 | 5.4 |

### Example 5: Preparation of a Quantum Dot Printing Ink Comprising Quinoline

An agitator is placed in a vial, which is washed cleanly and then transferred to a glove box. In the vial, 9.5 g of a quinoline solvent is prepared. A quantum dot solid is obtained through separating quantum dots from a solution by using acetone and performing centrifugation. In the glove box, 0.5 g of the quantum dot solid is weighed and added to the solvent system in the vial. The mixture is stirred at 60° C. to allow the quantum dots to be dispersed completely, and then cooled to the room temperature. The resulting quantum dot solution is filtered by a PTFE membrane of 0.2 μm, and then sealed for storage.

### Example 6: Preparation of a Quantum Dot Printing Ink Comprising Quinoline and Dodecylbenzene

An agitator is placed in a vial, which is washed cleanly and then transferred to a glove box. In the vial, 9.5 g of a mixed solvent of quinoline and dodecylbenzene (a weight ratio of 60:40) is prepared. A quantum dot solid is obtained through separating quantum dots from a solution by using acetone and performing centrifugation. In the glove box, 0.5 g of the quantum dot solid is weighed and added to the solvent system in the vial. The mixture is stirred at 60° C. to allow the quantum dots to be dispersed completely, and then cooled to the room temperature. The resulting quantum dot solution is filtered by a PTFE membrane of 0.2 μm, and then sealed for storage.

### Example 7: Preparation of a ZnO Nanoparticle Printing Ink Comprising Isoquinoline

An agitator is placed in a vial, which is washed cleanly and then transferred to a glove box. In the vial, 9.5 g of an isoquinoline solvent is prepared. In the glove box, 0.5 g of ZnO nanoparticle solid is weighed and added to the solvent system in the vial. The mixture is stirred at 60° C. to allow ZnO nanoparticles to be dispersed completely, and then cooled to the room temperature. The resulting ZnO nanoparticle solution is filtered by a PTFE membrane of 0.2 μm, and then sealed for storage.

### Example 8: Preparation of a ZnO Nanoparticle Printing Ink Comprising Isoquinoline and 3-Phenoxytoluene

An agitator is placed in a vial, which is washed cleanly and then transferred to a glove box. In the vial, 9.5 g of a mixed solvent of isoquinoline and 3-phenoxytoluene (a weight ratio of 60:40) is prepared. In the glove box, 0.5 g of ZnO nanoparticle solid is weighed and added to the solvent system in the vial. The mixture is stirred at 60° C. to allow ZnO nanoparticles to be dispersed completely, and then cooled to the room temperature. The resulting ZnO nanoparticle solution is filtered by a PTFE membrane of 0.2 μm, and then sealed for storage.

All the organic functional materials involved in the following examples are available commercially such as Jilin OLED Material Tech Co., Ltd (www.jl-oled.com), or synthesized by a method reported in the literature.

### Example 9: Preparation of a Printing Ink Comprising Quinoline for an Organic Light Emitting Layer

In this example, the organic functional material of the light emitting layer includes a phosphorescent host material and a phosphorescent emitter material, wherein the phosphorescent host material is selected from a derivative of carbazole as follows:

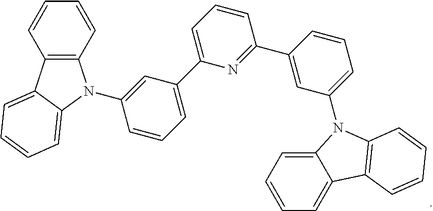 [SMILES: c1cc(-c2cccc(-c3cccc(-n4c5ccccc5c5ccccc54)c3)n2)cc(-n2c3ccccc3c3ccccc32)c1]

And the phosphorescent emitter material is selected from an iridium complex as follows:

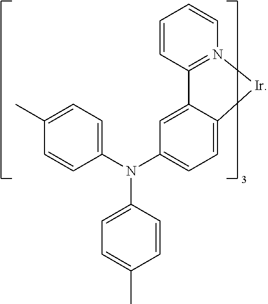

An agitator is placed in a vial, which is washed cleanly and then transferred to a glove box. In the vial, 9.8 g of a quinoline solvent is prepared. In the glove box, 0.18 g of the phosphorescent host material and 0.02 g of the phosphorescent emitter material are weighed and added to the solvent system in the vial. The mixture is stirred at 60° C. to allow the organic functional material to be dissolved completely, and then cooled to the room temperature. The resulting organic functional material solution is filtered by a PTFE membrane of 0.2 μm, and then sealed for storage.

### Example 10: Preparation of a Printing Ink Comprising Isoquinoline for an Organic Light Emitting Layer

In this example, the organic functional material of the light emitting layer includes a fluorescent host material and a fluorescent emitter material, wherein the fluorescent host material is selected from a derivative of spirofluorene as follows:

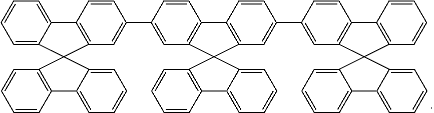 [SMILES: c1ccc2c(c1)-c1ccccc1C21c2ccccc2-c2ccc(-c3ccc4c(c3)C3(c5ccccc5-c5ccccc53)c3cc(-c5ccc6c(c5)C5(c7ccccc7-c7ccccc75)c5ccccc5-6)ccc3-4)cc21]

And the fluorescent emitter material is selected from the following compound:

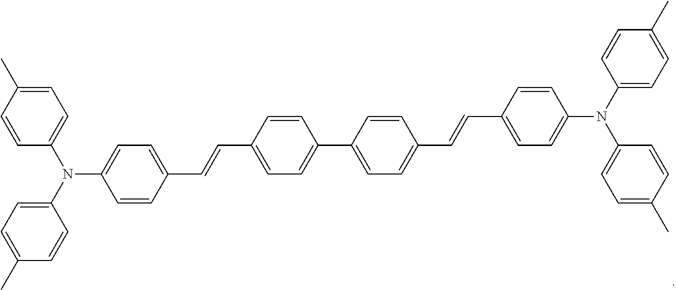 [SMILES: Cc1ccc(N(c2ccc(C)cc2)c2ccc(/C=C/c3ccc(-c4ccc(/C=C/c5ccc(N(c6ccc(C)cc6)c6ccc(C)cc6)cc5)cc4)cc3)cc2)cc1]

An agitator is placed in a vial, which is washed cleanly and then transferred to a glove box. In the vial, 9.8 g of an isoquinoline solvent is prepared. In the glove box, 0.19 g of the fluorescent host material and 0.01 g of the fluorescent emitter material are weighed and added to the solvent system in the vial. The mixture is stirred at 60° C. to allow the organic functional material to be dissolved completely, and then cooled to the room temperature. The resulting organic functional material solution is filtered by a PTFE membrane of 0.2 μm, and then sealed for storage.

### Example 11: Preparation of a Printing Ink Comprising Quinoline and 3-Phenoxytoluene for an Organic Light Emitting Layer

In this example, the organic functional material of the light emitting layer includes a host material and a TADF material, wherein the host material is selected from a compound having the following structure:

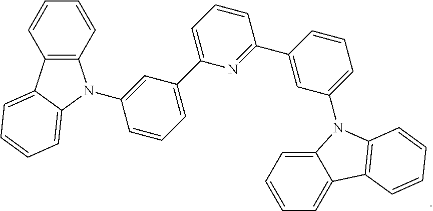 [SMILES: c1cc(-c2cccc(-c3cccc(-n4c5ccccc5c5ccccc54)c3)n2)cc(-n2c3ccccc3c3ccccc32)c1]

And the TADF material is selected from a compound having the following structure:

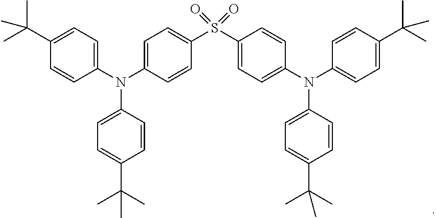 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

An agitator is placed in a vial, which is washed cleanly and then transferred to a glove box. In the vial, 9.8 g of a mixed solvent of quinoline and 3-phenoxytoluene (a weight ratio of 60:40) is prepared. In the glove box, 0.19 g of the host material and 0.01 g of the TADF material are weighed and added to the solvent system in the vial. The mixture is stirred at 60° C. to allow the organic functional material to be dissolved completely, and then cooled to the room temperature. The resulting organic functional material solution is filtered by a PTFE membrane of 0.2 μm, and then sealed for storage.

### Example 12: Preparation of a Hole Transport Material Printing Ink Comprising Quinoline

In this example, the printing ink includes a hole transport layer material having hole transport ability.

The hole transport material is selected from a derivative of triarylamine as follows:

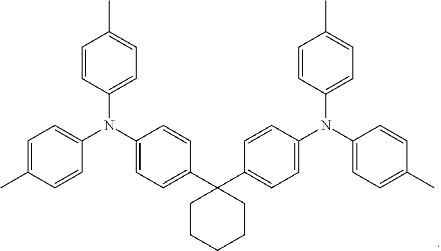

An agitator is placed in a vial, which is washed cleanly and then transferred to a glove box. In the vial, 9.8 g of a quinoline solvent is prepared. In the glove box, 0.2 g of the hole transport material is weighed and added to the solvent system in the vial. The mixture is stirred at 60° C. to allow the organic functional material to be dissolved completely, and then cooled to the room temperature. The resulting organic functional material solution is filtered by a PTFE membrane of 0.2 μm, and then sealed for storage.

### Example 13: Viscosity and Surface Tension Tests

The viscosity of the functional material ink is measured by DV-I Prime Brookfield rheometer, and the surface tension of the functional material ink is measured by SITA bubble pressure tensiometer.

According to the above tests, the viscosity and surface tension data of the functional material inks prepared in Example 5 to Example 12 are listed in the following table:

| Example | Viscosity (cPs) | Surface Tension (dyne/cm) |
|---|---|---|
| 5 | 5.4 ± 0.5 | 41.0 ± 0.5 |
| 6 | 5.5 ± 0.5 | 37.2 ± 0.5 |
| 7 | 4.5 ± 0.3 | 41.7 ± 0.5 |
| 8 | 4.7 ± 0.3 | 40.1 ± 0.5 |
| 9 | 5.6 ± 0.5 | 41.3 ± 0.5 |
| 10 | 5.1 ± 0.5 | 42.1 ± 0.2 |
| 11 | 5.8 ± 0.5 | 38.3 ± 0.5 |
| 12 | 5.9 ± 0.5 | 41.6 ± 0.5 |

### Example 14: Preparation of a Functional Layer of the Electronic Device with the Printing Ink of the Present Disclosure

A functional layer, such as a light emitting layer and a charge transport layer, of a light emitting diode can be prepared from the printing ink of the present disclosure through ink-jet printing, wherein the printing ink utilizes the heteroaromatic-based organic solvent having formula (I) and includes the functional material.

The printing method includes the steps of: charging the ink comprising the functional material in an ink cartridge, which is equipped in an ink-jet printer such as Dimatix Materials Printer DMP-3000 (Fujifilm); and regulating the waveform, pulse time and voltage for jetting the ink to optimize the ink-jetting process and realize stability in the range of ink jetting. A method for manufacturing an OLED/QLED device including a functional material film as a light emitting layer includes utilizing a piece of glass in a thickness of 0.7 mm that is sputtered with indium tin oxide (ITO) electrode patterns as a substrate of the OLED/QLED device. A pixel defining layer is patterned on the ITO to form holes for depositing the printing ink inside. Then the HIL/HTL material is jetted to the holes and dried at a high temperature in a vacuum to remove the solvent, and thus obtaining an HIL/HTL film. After that, the printing ink comprising the luminescent functional material is jetted to the HIL/HTL film and dried at a high temperature in a vacuum to remove the solvent, and thus obtaining a light-emitting film. The printing ink comprising the functional material having electron transport ability is jetted to the light-emitting film and dried at a high temperature in a vacuum to remove the solvent, and thus obtaining an electron transport layer (ETL). When utilizing the organic electron transport material, the ETL also can be formed by vacuum thermal evaporation. Finally, the OLED/QLED device is packaged.

What described above are several embodiments of the present disclosure, and they are specific and in details, but not intended to limit the scope of the present disclosure. It will be understood by those skilled in the art that various modifications and improvements can be made without departing from the concept of the present disclosure, and all these modifications and improvements are within the scope of the present disclosure. The scope of the present disclosure shall be subject to the claims attached.

1. A formulation for printed electronics comprising at least one functional material and a solvent system including at least one organic solvent, wherein the organic solvent comprises at least one heteroaromatic-based organic solvent having formula (I): 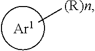
wherein Ar¹ is a heteroaromatic ring containing 5 to 10 carbon atoms, n is an integer equal to or larger than 0, and R is a substituent group, wherein the heteroaromatic-based organic solvent having formula (I) has a boiling point equal to or larger than 150° C. and is capable of being evaporated from the solvent system to allow a film of the functional material to be formed.

2. The formulation for printed electronics of claim 1, Wherein the heteroaromatic-based organic solvent having formula (I) has a viscosity at 25° C. from 1 cPs to 100 cPs.

3. The formulation for printed electronics of claim 1, wherein the heteroaromatic-based organic solvent having formula (I) has a surface tension at 25° C. from 19 dyne/cm to 50 dyne/cm.

4. The formulation for printed electronics of claim 1, wherein the heteroaromatic-based organic solvent having formula (I) has a structure selected from one of formulas as follows: 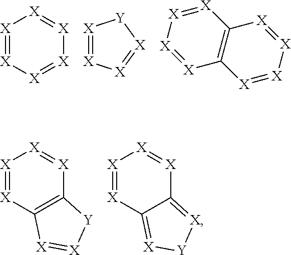
where,
X is CR¹ or N,
and Y is selected from CR²R³, SiR⁴R⁵, NR⁶, C(═O), S, S(═O)₂ or O;
in each formula, at least one X or Y is a non-carbon atom;
and R¹, R², R³, R⁴, R⁵ and R⁶ each are independently selected from H, D, straight chain alkyl, straight chain alkoxy or straight chain thioalkoxy each containing 1 to 20 carbon atoms, branched or cyclic alkyl, branched or cyclic alkoxy, branched or cyclic thioalkoxy or branched or cyclic silyl each containing 3 to 20 carbon atoms, C₁-C₂₀ substituted keto, C₂-C₂₀ alkoxycarbonyl, C₇-C₂₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 40-membered aromatic or heteroaromatic rings, or 5- to 40-membered aryloxy or heteroaryloxy, wherein one or more of R1, R2, R3, R4, R5 and R6 can form a monocyclic or a polycyclic aliphatic or aromatic ring system with each other and/or with a ring linked thereto.

5. The formulation for printed electronics of claim 1, wherein Ar¹ is selected from one of structural units as follows:

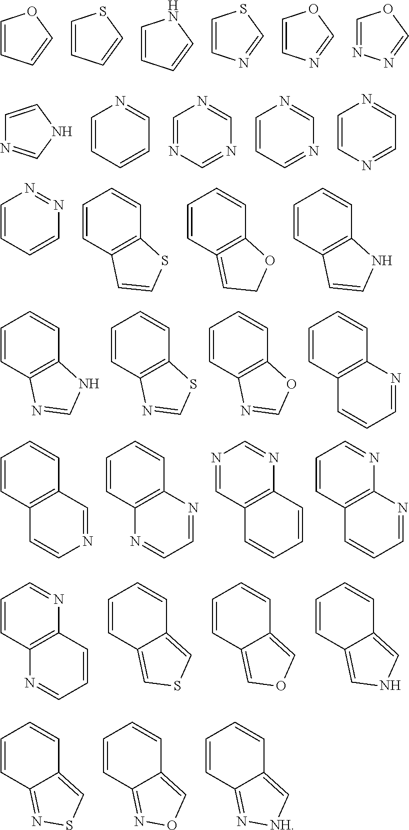

6. The formulation for printed electronics of claim 1, wherein R is selected from straight chain alkyl, straight chain alkoxy or straight chain thioalkoxy each containing 1 to 20 carbon atoms, branched or cyclic alkyl, branched or cyclic alkoxy, branched or cyclic thioalkoxy or branched or cyclic silyl each containing 3 to 20 carbon atoms, C₁-C₂₀ substituted keto, C₂-C₂₀ alkoxycarbonyl, C₇-C₂₀ aryloxycarbonyl, cyano (—CN), carbamoyl (—C(═O)NH₂), haloformyl (—C(═O)—X, wherein X is a halogen atom), formyl (—C(═O)—H), isocyano, isocyanate group, thiocyanate group, isothiocyanate group, hydroxyl, nitro, CF₃ group, Cl, Br, F, crosslinkable group, substituted or unsubstituted 5- to 40-membered aromatic or heteroaromatic rings, or 5- to 40-membered aryloxy or heteroaryloxy, wherein one or more of R can form a monocyclic or a polycyclic aliphatic or aromatic ring system with each other and/or with a ring linked thereto.

7. The formulation for printed electronics of claim 1, wherein the heteroaromatic-based organic solvent having formula (I) is selected from the group consisting of 2-phenylpyridine, 3-phenylpyridine, 4-(3-phenylpropyl)pyridine, quinoline, isoquinoline, 8-hydroxyquinoline, methyl 2-furoate, ethyl 2-furoate, and any combination thereof.

8. The formulation for printed electronics of claim 1, wherein the solvent system is a mixture further comprising at least one other solvent, wherein the organic solvent having formula (I) accounts for 50% or above of a total weight of the mixture.

9. The formulation for printed electronics of claim 1, wherein the functional material is an inorganic nanomaterial.

10. The formulation for printed electronics of claim 1, wherein the functional material is a quantum dot material.

11. The formulation for printed electronics of claim 1, wherein the functional material is a luminescent quantum dot material emitting light having a wavelength between 380 nm and 2500 nm.

12. The formulation for printed electronics of claim 1, wherein the formulation for printed electronics comprises an inorganic functional material selected from the group consisting of binary or multinary semiconductor compounds of Group IV, II-VI, II-V, III-V, III-VI, IV-VI, I-III-VI, II-IV-VI and II-IV-V of the Periodic Table of the Elements, and any combination thereof.

13. The formulation for printed electronics of claim 1, wherein the functional material is selected from the group consisting of a luminescent perovskite nanomaterial, a metal nanoparticle material, a metal oxide nanoparticle material, and any combination thereof.

14. The formulation for printed electronics of claim 1, wherein the functional material is an organic functional material.

15. The formulation for printed electronics of claim 1, wherein the organic functional material is selected from the group consisting of a hole injection material, a hole transport material, an electron transport material, an electron injection material, an electron blocking material, a hole blocking material, an emitter, a host material, an organic dye, and any combination thereof.

16. The formulation for printed electronics of claim 14, wherein the organic functional material includes at least one host material and at least one emitter.

17. The formulation for printed electronics of claim 1, wherein the formulation for printed electronics comprises 0.3%-30% by weight of the functional material, and 70%-99.7% by weight of the solvent system.

18. An electronic device, comprising a functional layer printed or coated from the formulation for printed electronics of claim 1.

19. The electronic device of claim 18, wherein the electronic device is selected from the group consisting of a quantum dot light emitting diode, a quantum dot photovoltaic cell, a quantum dot light emitting electrochemical cell, a quantum dot field effect transistor, a quantum dot light emitting field effect transistor, a quantum dot laser, a quantum dot sensor, an organic light emitting diode, an organic photovoltaic cell, an organic light emitting electrochemical cell, an organic field effect transistor, an organic light emitting field effect transistor, an organic laser, an organic sensor, and any combination thereof.

20. A method for preparing a functional material film, comprising spreading the formulation for printed electronics of claim 1 on a substrate through a printing or coating process, wherein the printing or coating process is selected from the group consisting of ink-jet printing, nozzle printing, typographic printing, screen printing, dip coating, spin coating, blade coating, roller printing, torsion roller printing, lithographic printing, flexographic printing, rotary printing, spray coating, brush coating, pad printing, slot die coating, and any combination thereof.
